(19) United States
(12) Patent Application Publication
(10) Pub. No.: US 2026/0246526 A1
(43) Pub. Date: Aug. 20, 2026

(54) METHOD FOR OPERATING A BEAM DEVICE, COMPUTER PROGRAM AND BEAM DEVICE FOR CARRYING OUT THE METHOD AS WELL AS A METHOD FOR GENERATING A TRAINING DATA SET AND A METHOD FOR TRAINING A MACHINE LEARNING MODEL

(71) Applicant: Carl Zeiss Microscopy GmbH, Jena (DE)

(72) Inventors: Pascal Maria ANGER, Aalen (DE); Rainer ARNOLD, Thalfingen (DE); Michal POSTOLSKI, Barlinek (PL); Jonas UMLAUFT, Regensburg (DE); Stratis TZOUMAS, Pullach im Isartal (DE); Michael PANCHENKO, Muenchen (DE); Ivan RODRIGUEZ, Garching bei Muenchen (DE); Fabio PERUZZO, Trier (DE); Francisco MATOS, Muenchen (DE)

(73) Assignee: Carl Zeiss Microscopy GmbH, Jena (DE)

(21) Appl. No.: 19/434,045

(22) Filed: Dec. 29, 2025

(30) Foreign Application Priority Data
Jan. 2, 2025 (GR) 20250100002

(51) Int. Cl. H04B 7/06; H04L 41/16

(52) U.S. Cl. CPC H04B 7/06952; H04L 41/16

(57) ABSTRACT

The system described herein relates to operating a beam device for obtaining information about an object. Moreover, the invention relates to a computer program product having a program code, which, when executed, controls the beam device in such a way that the method for operating the beam device is carried out. Additionally, the invention relates to a method for generating a training data set for a processing unit and/or for a machine learning model. Furthermore, the invention relates to a method for training a machine learning model of a beam device. The processing unit determines which machine learning model of a plurality of machine learning models is to be used for determining control values of control parameters. The control values of the control parameters are used to operate the control unit for generating the information about the object.

### TECHNICAL FIELD

This application relates to operating a beam device to obtain information about an object and, more particularly, to generating a training data set for a processing unit of a beam device and/or for a machine learning model to obtain information about an object.

### BACKGROUND

Electron beam devices, in particular a scanning electron microscope (also referred to as SEM below) and/or a transmission electron microscope (also referred to as TEM below), are used to examine objects (also referred to as samples) in order to obtain knowledge with respect to the properties and behavior of the objects under certain conditions. In an SEM, an electron beam (also referred to as primary electron beam below) is generated using a beam generator and focused on an object to be examined by way of a beam guiding system. An objective lens is used for focusing purposes. The primary electron beam is guided over a surface of the object to be examined using a deflection device. This is also referred to as scanning. The area scanned by the primary electron beam is also referred to as scanning region. Here, the electrons of the primary electron beam interact with the object to be examined. Interaction particles and/or interaction radiation result as a consequence of the interaction. By way of example, the interaction particles are electrons. In particular, electrons are emitted by the object—the so-called secondary electrons—and electrons of the primary electron beam are scattered back—the so-called backscattered electrons. The interaction particles form the so-called secondary particle beam and are detected by at least one particle detector. The particle detector generates detection signals which are used to generate an image of the object. An imaging of the object to be examined is thus obtained. By way of example, the interaction radiation is x-ray radiation or cathodoluminescent light. At least one radiation detector is used to detect the interaction radiation.

In the case of a TEM, a primary electron beam is likewise generated using a beam generator and directed onto an object to be examined using a beam guiding system. The primary electron beam passes through the object to be examined. When the primary electron beam passes through the object to be examined, the electrons of the primary electron beam interact with the material of the object to be examined. The electrons passing through the object to be examined are imaged onto a luminescent screen or onto a detector—for example in the form of a camera—by a system that includes an objective. By way of example, the aforementioned system additionally also includes a projection lens. Here, imaging may also take place in the scanning mode of a TEM. Usually, such a TEM is referred to as STEM. Additionally, provision may be made for detecting electrons scattered back at the object to be examined and/or secondary electrons emitted by the object to be examined using at least one further detector in order to image the object to be examined.

Combining the function of an STEM and an SEM in a single particle beam device is known. It is therefore possible to carry out examinations of objects with an SEM function and/or with an STEM function using this particle beam device.

Moreover, a particle beam device in the form of an ion beam column is known. Ions used for processing an object are generated using an ion beam generator arranged in the ion beam column. By way of example, material of the object is ablated, or material is applied onto the object during the processing. The ions are additionally or alternatively used for imaging.

Furthermore, the prior art discloses the practice of analyzing and/or processing an object in a particle beam device using, on the one hand, electrons and, on the other hand, ions. By way of example, an electron beam column having the function of an SEM is arranged at the particle beam device. Additionally, an ion beam column, which is explained above, is arranged at the particle beam device. The electron beam column with the SEM function serves, in particular, for examining further the processed or unprocessed object, but also for processing the object.

An object may be imaged with a high spatial resolution using an electron beam device. In particular, imaging an object is achieved by a very small diameter of the primary electron beam in the plane of the object. Further, the spatial resolution may improve the higher the electrons of the primary electron beam are initially accelerated in the electron beam device and decelerated to a desired energy (referred to as landing energy) at the end of the objective lens or in the region of the objective lens and the object. By way of example, the electrons of the primary electron beam are accelerated using an acceleration voltage of 2 kV to 30 kV and guided through an electron column of the electron beam device. The electrons of the primary electron beam are only decelerated to the desired landing energy, with which the electrons are incident on the object, in the region between the objective lens and the object. By way of example, the landing energy of the electrons in the primary electron beam lies in the range between 10 eV and 30 keV.

There are objects which, on account of their structure, may only be expediently examined in an electron beam device if the electrons in the primary electron beam incident on these objects only have a low landing energy, for example an energy of less than 100 eV. Electrons with such low energy for example ensure that these specific objects are not destroyed and/or do not charge upon irradiation by electrons. Further, electrons at such low energies are particularly suitable for obtaining an image with a high surface sensitivity (i.e. a particularly good information content with respect to the topography and/or the material of the surface of the object) of an object to be examined.

When generating an image of the object, the user of an electron beam device is always prudent to obtain the ideal image quality of an image of the object which is required for examining an object. Expressed differently, a user always wishes to generate an image of the object with such a high image quality that the user is able to analyze the object to be examined well on account of the image and the image information contained therein. Here, the image quality may be determined using, for example, objective criteria. By way of example, the image quality of an image becomes better with increasing resolution in the image or with increasing contrast. Alternatively, the image quality may be determined on the basis of subjective criteria. Here, a user determines individually as to whether or not an obtained image quality is sufficient. However, what may by all means occur in this case is that the image quality deemed sufficient by a first user is not considered sufficient by a second user. By way of example, the image quality of an image of an object may also be determined on the basis of the signal-to-noise ratio of the detector signal. The image quality is not sufficiently good in the case of a signal-to-noise ratio in the range from 0 to 5. By way of example, if the signal-to-noise ratio lies in the range from 20 to 40, this is referred to as a good signal-to-noise ratio (and hence also a good and sufficient image quality). The direction of the secondary particle beam may also be a measure for the image quality. The secondary electrons may be emitted from the object at different solid angles. Further, the backscattered electrons may be backscattered into different solid angles at the object. The direction of the secondary particle beam (i.e. the solid angles along which the secondary particle beam extend) may be influenced by tilting the primary electron beam and/or the object in relation to the optical axis of the electron beam device. As a result of this, it is possible, on the one hand, to select the direction of the secondary particle beam in such a way that the secondary particle beam is incident on a desired detector. On the other hand, it is possible to influence both the number of the generated secondary electrons and the number of the backscattered electrons by way of the aforementioned tilting. By way of example, if the primary electron beam is incident into the object parallel to a crystal lattice of an object, the number of secondary electrons and/or backscattered electrons reduces. The detection signal becomes weaker. This leads to reduction in the image quality. It is possible to increase the number of secondary electrons and number of backscattered electrons by setting the tilt of the primary electron beam. Using such a setting, it is possible to differentiate crystals with a first orientation from crystals with a second orientation on the basis of the strength of the detection signal.

As mentioned above, it is also possible to detect interaction radiation, for example cathodoluminescent light and x-ray radiation. When detecting interaction radiation, a user of an electron beam device may by all means be prudent to obtain the quality of the representation of the detection signals of a radiation detector based on the detected interaction radiation which is required for examining an object. By way of example, if x-ray radiation is detected by the radiation detector, the quality of the representation is determined for example by a good detection signal of the radiation detector. By way of example, the latter is embodied as an EDX detector. By way of example, the quality of the representation is then influenced by the count rate of the detected x-ray quanta on the one hand and, on the other hand, by the full width at half maximum of the measured peaks in the x-ray spectrum. The quality of the representation of the detection signals increases with higher count rate and smaller full width at half maximum. By way of example, if cathodoluminescent light is detected by a radiation detector, the quality of the representation may likewise be determined, for example, by a good detection signal of the radiation detector. By way of example, the quality of the representation is determined by the count rate of the detected photons of the cathodoluminescent light. The count rate may be influenced by a suitable optical unit for light. Further, the primary electron beam may be set in such a way that the object emits as many photons as possible overall or as many photons as possible within a specific wavelength interval.

In order to obtain a good image quality of an image and/or a good representation of the detection signals based on the detected interaction radiation, which image and/or representation is/are generated using an electron beam device, a user of an electron beam device known from the prior art initially selects a desired landing energy with which the electrons are incident on the object. Following this, the user selects settings of further control parameters of at least one control unit. By way of example, the control parameters are physical variables, in particular a control current or a control voltage, but also, for example, the ratio of physical variables, in particular an amplification of physical variables. The values of the physical variables are adjustable at the control units or using the control units and these control and/or feed the units of the electron beam device in such a way that desired physical effects, for example, the generation of specific magnetic fields and/or electrostatic fields, are brought about.

A first control parameter of a first control unit sets the contrast in the generated image. In principle, the contrast is the brightness difference (i.e. the intensity difference) between the brightest pixel with a maximum luminance Lₘₐₓ and the darkest pixel with a minimum luminance Lₘᵢₙ in an image. A smaller brightness difference between the two pixels means a low contrast. A larger brightness difference between the two pixels means a high contrast. By way of example, the contrast may be specified as Weber contrast or as Michelson contrast. Here, the following applies for the Weber contrast:

$${K}_{W} = \frac{{L}_{max}}{{L}_{min}} - 1 with 0 \leq {K}_{W} \leq ∞ \qquad [ 1 ]$$

The following applies for the Michelson contrast:

$${K}_{M} = \frac{{L}_{max} - {L}_{min}}{{L}_{max} + {L}_{min}} with 0 \leq {K}_{M} \leq 1 \qquad [ 2 ]$$

The contrast which is substantially generated by the secondary electrons is determined by the topography of the surface of the object. On the other hand, the contrast which is substantially generated by the backscattered electrons is substantially determined by the material of the imaged object region. It is also referred to as material contrast. The material contrast depends on the mean atomic number of the imaged region of the object. By way of example, the contrast increases when a higher gain factor is set at an amplifier of the detector, where the detector is used to detect the secondary electrons and/or backscattered electrons. The amplifier amplifies the detection signal generated by the detector. Analogously, the contrast, for example, decreases when a smaller gain factor is set at the amplifier of the detector.

A second control parameter of a second control unit sets the brightness in the generated image. In principle, the brightness in an image is related to each pixel in the image. A first pixel with a higher brightness value than a second pixel appears brighter in the image than the second pixel. By way of example, the brightness is set by setting a gain factor and/or an offset and/or a signal shift of the detection signal of the detector. Here, the brightness of each pixel in the image is increased or lowered by an identical amount, for example also using a color table stored in a memory unit, with a specific brightness corresponding to a color included in the color table.

A third control parameter of a third control unit serves, for example, for actuating the objective lens, the latter being used to set the focusing of the primary electron beam onto the object.

A fourth control parameter for actuating a fourth control unit serves to center the primary electron beam in the objective lens. By way of example, the fourth control unit serves to set electrostatic and/or magnetic units of the electron beam device, using which the centering of the primary electron beam in the objective lens is set.

Moreover, the image quality of an image of the object and/or the quality of the representation of the detection signals based on the detected interaction radiation is/are influenced by a fifth control parameter of a fifth control unit for controlling and setting electrostatic and/or magnetic deflection units which are used in the electron beam device for a so-called “beam shift”. As a result of this, it is possible to set the position of the scanning region and optionally displace the scanning region to a desired position. This may occur without the use of a sample stage (also referred to as object holder below), on which the object is arranged. By way of example, if the scanning region migrates out of the actual region of the object observed using the electron beam device due to a change in the settings on the electron beam device, the primary electron beam is displaced in such a way as a result of translational movements in the case of a “beam shift” that the scanning region once again lies in the desired observed region.

A stigmator used in an electron beam device may also influence the image quality of the image of the object and/or the quality of the representation of the detection signals based on the detected interaction radiation. The stigmator—a magnetic and/or electrostatic multi-pole element—is used, in particular, for correcting an astigmatism. The stigmator may be set by a sixth control unit using a sixth control parameter.

The image quality of an image of the object and/or the quality of the representation of the detection signals based on the detected interaction radiation may however also be influenced by the position of a mechanically displaceable unit of the electron beam device. By way of example, the image quality is influenced by the position of an aperture which is used to shape and delimit the primary electron beam in the electron beam device.

The image quality of an image of the object and/or the quality of the representation of the detection signals based on the detected interaction radiation may further be influenced by the so-called scan rotation. This is a rotation of the scanning region in the plane of the scanning region about an optical axis of the electron beam device.

Therefore, in order to obtain a desired image quality of an image of an object and/or a desired quality of the representation of the detection signals based on the detected interaction radiation, the user should take into account as many of the aforementioned control parameters as possible and/or further control parameters not specified here, with the physical effects obtained by the individual control parameters influencing one another in turn.

The following methods for ascertaining suitable values of the control parameters are known, using which a desired image quality and/or quality of the representation of the detection signals based on the detected interaction radiation may be obtained:
By way of example, mathematical models may be used to ascertain suitable values of the individual control parameters in order to obtain a desired image quality and/or quality of the representation of the detection signals based on the detected interaction radiation. However, the calculated and theoretical values of the control parameters are often not suited to obtain a really good image quality and/or good representation of the detection signals based on the detected interaction radiation. This may be due to the fact that, for example, not all control parameters are taken into account in the mathematical models and/or the mathematical models are based on simplified assumptions which are more complicated in reality.
In a further known method, provision is made for ascertaining the values of the various control parameters by experiment, with, for example, a reference sample being used for ascertainment by experiment. The ascertained values of the control parameters are used to set the control units of the electron beam device. However, it is disadvantageous that an object to be examined and imaged does not always correspond to the reference sample, in particular with respect to the material composition and the topography. This may lead to optical aberrations and hence to a deterioration in the image quality which is actually obtained.
A further known method sets the image quality and/or the representation of the detection signals based on the detected interaction radiation using a manual search for the desired image quality for an object to be imaged and/or for the desired representation of the detection signals based on the detected interaction radiation. Here, the desired landing energy of the electrons, with which the electrons of the primary electron beam are incident on the object to be examined, is selected first. Subsequently, the brightness, the contrast, the focusing, the centering of the primary electron beam in the objective lens, the beam shift and/or the position of the adjustable unit are varied and matched to one another by trials in such a way until the desired image quality and/or the desired representation is/are obtained. Such a procedure is very complicated, as it has to be carried out for each setting of the landing energy.

It is referred to DE 10 2016 208 689 A1 as prior art.

### SUMMARY OF THE INVENTION

The system described herein is therefore based on using values of control parameters for control units that actuate components of a beam device that are easy to obtain, with the values of the control parameters ensuring, in particular, a desired image quality of an image of an object and/or a desired representation of the detection signals based on the detected interaction radiation. Features of the system described herein emerge from the following description, the attached claims and/or the attached drawings.

A method according to the system described herein is used to operate a beam device to obtain information about an object. Examples of the beam device are discussed further below. Furthermore, examples of the information about the object are discussed further below.

The method according to the system described herein includes obtaining, using a processing unit, first data from a database being connected to the processing unit. The processing unit is associated with the beam device. For example, the processing unit may be a processing unit and/or a processor of the beam device. Additionally or alternatively, the processing unit may be a unit separated from the beam device, but which is connected to the beam device. The connection between the processing unit and the beam device may be wireless or by wire. The database may be a database associated with the beam device. For example, the database may be a database of the beam device. Additionally or alternatively, the database may be a unit separated from the beam device, but which is connected to the beam device. The connection between the processing unit and the database may be wireless or by wire.

As mentioned above, the first data is obtained from the database. The first data includes object data about the object, data about a plurality of machine learning models as well as first range data about a range of possible values of at least one first control parameter used to control a control unit of the beam device.

The object data may include specific information about the object. For example, the object data may include at least one of the following: (a) information about the material or the materials in the object, (b) the size of the object and (c) the temperature of the object. The invention is not limited to any particular kind of object data. Rather, any information which is suitable for the invention may be used.

A machine learning model is a program that provides outputs based on data inputs which have not been seen by the machine learning model before. Machine learning models are known in the art. Examples of machine learning models are discussed further below.

As mentioned above, the at least one first control parameter is used to control the control unit of the beam device. Examples of the first control parameter are discussed further elsewhere herein. The first range data includes a range of all possible values of the first control parameter. Examples of the range of values of the first control parameter are discussed further below.

Furthermore, the method according to the system described herein includes, on the one hand, determining, using the processing unit, a first machine learning model of the plurality of machine learning models based on the first data and, on the other hand, providing the object data and the first range data as input data to the first machine learning model. Additionally, the method according to the system described herein includes determining, using the first machine learning model, a control value of the first control parameter, where the control value of the first control parameter is an output of the first machine learning model. For example, the machine learning model uses the object data and the first range data to determine the control value of the first control parameter. The control value of the first control parameter is used to provide the information about the object at a later stage of the method described herein. The information about the object thus may fulfil a given standard.

The method according to the system described herein also includes obtaining, using the processing unit, second data from the database. The second data includes the object data about the object, the data about the plurality of machine learning models as well as second range data about a range of possible values of at least one second control parameter to control the control unit of the beam device. The object data and the machine learning models are discussed further elsewhere herein. As mentioned above, the at least one second control parameter is used to control the control unit of the beam device. Examples of the second control parameter are discussed further elsewhere herein. The second range data includes a range of all possible values of the second control parameter. Examples of the range of values of the second control parameter are discussed further below.

Furthermore, the method according to the system described herein includes determining, using the processing unit, a second machine learning model of the plurality of machine learning models based on the second data. Determining the second machine learning model may additionally be based on the determined control value of the first control parameter. Additionally, the method according to the system described herein includes providing the object data and the second range data as input data to the second machine learning model. The method according to the system described herein also includes determining, using the second machine learning model, a control value of the second control parameter. The control value of the second control parameter is an output of the second machine learning model. For example, the machine learning model uses the object data and the second range data to determine the control value of the second control parameter. The control value of the second control parameter is used to provide the information about the object at a later stage of the method according to the system described herein. The information about the object thus may fulfil a given standard.

Furthermore, the method according to the system described herein includes using the determined control value of the first control parameter and the determined control value of the second control parameter to operate the control unit. Additionally, the method according to the system described herein includes generating, using the beam device and the control unit of the beam device, the information about the object. Examples of the information about the object are discussed further below.

In an embodiment of the method according to the system described herein, the first machine learning model and the second machine learning model may be identical. Therefore, the method according to the system described herein uses the same machine learning model for several control parameters (for example, the first control parameter and the second control parameter). The method steps according to the system described herein with respect to the several control parameters may be carried out simultaneously.

In a further embodiment of the method according to the system described herein, the first machine learning model is different to the second machine learning model. In contrast to the prior art, the system described herein provides a processing unit which determines which machine learning model of a plurality of machine learning models is to be used to determine the control value of the first control parameter and to determine the control value of the second control parameter. The processing unit chooses a machine learning model based on the first data, on the one hand, and the second data and, in particular, the determined control value of the first control parameter on the other hand. Therefore, the system described herein provides for the processing unit to choose a specific machine learning model from the plurality of machine learning models which machine learning model may determine specific control values of the first control parameter and of the second control parameter. The specific control values of the first control parameter and of the second control parameter are used to operate the control unit to generate the information about the object, in particular, in a rather short time and/or in a good quality and/or in a required quality. The method according to the system described herein also provides that each machine learning model used in the method according to the system described herein may use different ranges of possible values of the first control parameter and the second control parameter when determining the control values of the first control parameter and the second control parameter. Therefore, the processing unit may always choose a specific machine learning model from the plurality of machine learning models, where the specific machine learning model may operate better than other machine learning models of the plurality of machine learning models for a specific range of possible values of the first control parameter or the second control parameter.

In an embodiment of the method according to the system described herein, it is additionally or alternatively provided that generating the information about the object includes generating an image of the object. For example, an image of the object is generated using a light microscope, a laser beam device and/or a particle beam device. Additionally or alternatively, generating the information about the object includes generating a spectroscopy analysis about the object. For example, interaction radiation of an interaction between the beam of the beam device and the object is detected using a detector. The interaction radiation may be x-ray radiation or cathodoluminescent light. By way of example, a radiation detector is used to detect the interaction radiation. Further examples are discussed further elsewhere herein.

In a further embodiment of the method according to the system described herein, it is additionally or alternatively provided that determining the first machine learning model and/or the second machine learning model of the plurality of machine learning models includes determining one of the following machine learning models: a heuristic autotuning algorithm, a supervised learning algorithm and a reinforcement algorithm. In other words, the plurality of machine learning models may include the heuristic autotuning algorithm, the supervised learning algorithm and/or a reinforcement algorithm. The aforementioned algorithms are well known in the art. Therefore, the algorithms are just briefly discussed as follows:
The heuristic autotuning algorithm may provide control values of the first control parameter and the second control parameter to obtain information about the object based (a) on the object data and (b) on values in the first range data about the range of possible values of the first control parameter and/or on values in the second range data about the range of possible values of the second control parameter. Additionally, the heuristic autotuning algorithm may evaluate the quality of the obtained information about the object. Furthermore, the heuristic autotuning algorithm selects the best value of the control values obtained as outcome of the algorithm, which control values are used to control the control unit to provide the information about the object which information fulfils, for example, a good quality standard.
The supervised learning algorithm provides a model that predicts, as an outcome of this model, the control value of the first control parameter and/or the control value of the second control parameter, where the control values are used to control the control unit to provide the information about the object which information fulfils, for example, a good quality standard. The object data and the first range data about the range of possible values of the first control parameter and/or the second range data about the range of possible values of the second control parameter are used as input of this model.
The reinforcement algorithm is a trained algorithm. The algorithm acquires, in a first step, the control value of the first control parameter and/or the control value of the second control parameter, where the control values are used to control the control unit to provide the information about the object. Furthermore, in a second step, the algorithm evaluates the acquired information and selects the next value of the first range data about the range of possible values of the first control parameter and/or the next value of the second range data about the range of possible values of the second control parameter. The first step and the second step are repeated until the acquired information about the object is deemed sufficiently good and/or changes of the values of the first range data and/or the second range data are small.

It is noted that the invention is not restricted to the machine learning models mentioned-above. Rather, any machine learning model suitable for the invention may be used. In yet a further embodiment of the method according to the system described herein, it is additionally or alternatively provided that the method includes at least one of the following:
(i) using, as the first control parameter, a first physical variable;
(ii) using, as the first control parameter, a first control current or a first control voltage;
(iii) using, as the first control parameter, a first ratio of physical variables; and
(iv) using, as the first control parameter, a first amplification of physical variables.

In an embodiment of the method according to the system described herein, it is additionally or alternatively provided that the method includes at least one of the following:
(i) using, as the second control parameter, a second physical variable;
(ii) using, as the second control parameter, a second control current or a second control voltage;
(iii) using, as the second control parameter, a second ratio of physical variables; and
(iv) using, as the second control parameter, a second amplification of physical variables.

In a further embodiment of the method according to the system described herein, it is additionally or alternatively provided that the method includes at least one of the following:
(i) using, as the first control parameter, one of the following: a first contrast parameter that sets the contrast of the information about the object, a first brightness parameter that sets the brightness of the information about the object, a first actuating parameter that serves to actuate an objective lens of the beam device, a first setting parameter that serves to set an electrostatic and/or magnetic unit of the beam device, a first controlling parameter that serves to control and set an electrostatic and/or magnetic deflection unit of the beam device to achieve a shift of the beam of the beam device and a first stigmator parameter that sets a stigmator of the beam device;
(ii) using, as the second control parameter, one of the following: a second contrast parameter that sets the contrast of the information about the object, a second brightness parameter that sets the brightness of the information about the object, a second actuating parameter that serves to actuate the objective lens of the beam device, a second setting parameter that serves to set the electrostatic and/or magnetic unit of the beam device, a second controlling parameter that serves to control and set the electrostatic and/or magnetic deflection unit of the beam device to achieve a shift of the beam of the beam device and a second stigmator parameter that sets the stigmator of the beam device.

The invention is not restricted to the examples given for the first control parameter and/or the second control parameter. Rather, any control parameter which is suitable for the invention, may be used. For example, the following control parameters may be used as the first control parameter and/or the second control parameter:
A control parameter may set the contrast in the information about the object, where the information is given by a generated image. In principle, the contrast is the brightness difference (i.e. the intensity difference) between the brightest pixel with a maximum luminance Lₘₐₓ and the darkest pixel with a minimum luminance Lₘᵢₙ in an image. A smaller brightness difference between the two pixels means a low contrast. A larger brightness difference between the two pixels means a high contrast. By way of example, the contrast may be specified as Weber contrast or as Michelson contrast. Here, the following applies for the Weber contrast:

$${K}_{W} = \frac{{L}_{max}}{{L}_{min}} - 1 with 0 \leq {K}_{W} \leq ∞ \qquad [ 1 ]$$

The following applies for the Michelson contrast:

$${K}_{M} = \frac{{L}_{max} - {L}_{min}}{{L}_{max} + {L}_{min}} with 0 \leq {K}_{M} \leq 1 \qquad [ 2 ]$$

If the generated image has been generated using a particle beam device, the contrast which is substantially generated by secondary electrons is determined by the topography of the surface of the object. On the other hand, the contrast which is substantially generated by backscattered electrons is substantially determined by the material of the imaged object region. The contrast which is substantially generated by backscattered electrons is also referred to as material contrast. The material contrast depends on the mean atomic number of the imaged region of the object. By way of example, the contrast increases when a higher gain factor is set at an amplifier of the detector, where the detector is used to detect the secondary electrons and/or backscattered electrons. The amplifier amplifies the detection signal generated by the detector. Analogously, the contrast, for example, decreases when a smaller gain factor is set at the amplifier of the detector;
a further control parameter may set the brightness in the information about the object, where the information is given as a generated image. In principle, the brightness in an image is related to each pixel in the image. A first pixel with a higher brightness value than a second pixel appears brighter in the image than the second pixel. By way of example, the brightness is set by setting a gain factor and/or an offset and/or a signal shift of the detection signal of a detector of the beam device. Here, the brightness of each pixel in the image is increased or lowered by an identical amount, for example also using a color table stored in a memory unit, with a specific brightness corresponding to a color included in the color table;
yet a further control parameter may serve, for example, to actuate an objective lens of the beam device, where the objective lens is used to set the focusing of the beam of the beam device onto the object;
another control parameter may serve to center a beam of the beam device in the objective lens of the beam device. By way of example, the other control parameter may serve to set electrostatic and/or magnetic units of the beam device, using which the centering of a particle beam of the beam device in the objective lens is set;
the image quality of an image of the object and/or the quality of the representation of the detection signals based on the detected interaction radiation is/are influenced by a control parameter that controls and sets electrostatic and/or magnetic deflection units which are used in the beam device in the form of a particle beam device for a so-called “beam shift”. As a result of this, it is possible to set the position of a scanning region and optionally displace the scanning region to a desired position. This may occur without the use of a sample stage (also referred to as object holder), on which the object is arranged. By way of example, if the scanning region migrates out of the actual region of the object observed using the particle beam device due to a change in the settings on the particle beam device, the primary particle beam of the particle beam device is displaced in such a way as a result of translational movements in the case of a “beam shift” that the scanning region once again lies in the desired observed region;
a stigmator used in a beam device in the form of a particle beam device may also influence the image quality of the image of the object and/or the quality of the representation of the detection signals based on the detected interaction radiation. The stigmator—a magnetic and/or electrostatic multipole element—is used, in particular, to correct an astigmatism. The stigmator may be set by using a stigmator control parameter;
the information about the object may also be influenced by the position of a mechanically displaceable unit of the beam device. By way of example, the information quality is influenced by the position of an aperture which is used to shape and delimit the beam in the beam device.

In yet a further embodiment of the method according to the system described herein, it is additionally or alternatively provided that the method includes at least one of the following:
(i) using, as the range of possible values of the first control parameter, a range between a minimum value and a maximum value of the first control parameter, where the minimum value and a maximum value of the first control parameter depend on a configuration of the control unit;
(ii) using, as the range of possible values of the first control parameter configured as a first contrast parameter that sets the contrast of the information about the object, a range between a minimum value and a maximum value of the first contrast parameter, where the minimum value and a maximum value of the first contrast parameter depend on a configuration of the control unit;
(iii) using, as the range of possible values of the first control parameter configured as a first brightness parameter that sets the brightness of the information about the object, a range between a minimum value and a maximum value of the first brightness parameter, where the minimum value and a maximum value of the first brightness parameter depend on a configuration of the control unit;
(iv) using, as the range of possible values of the first control parameter configured as a first actuating parameter that serves to actuate an objective lens of the beam device, a range between a minimum value and a maximum value of the first actuating parameter, where the minimum value and a maximum value of the first actuating parameter depend on a magnification of the beam device;
(v) using, as the range of possible values of the second control parameter, a range between a minimum value and a maximum value of the second control parameter, where the minimum value and a maximum value of the second control parameter depend on a configuration of the control unit;
(vi) using, as the range of possible values of the second control parameter configured as a second contrast parameter that sets the contrast of the information about the object, a range between a minimum value and a maximum value of the second contrast parameter, where the minimum value and a maximum value of the second contrast parameter depend on a configuration of the control unit;
(vii) using, as the range of possible values of the second control parameter configured as a second brightness parameter that sets the brightness of the information about the object, a range between a minimum value and a maximum value of the second brightness parameter, where the minimum value and a maximum value of the second brightness parameter depend on a configuration of the control unit;
(viii) using, as the range of possible values of the second control parameter configured as a second actuating parameter that serves to actuate an objective lens of the beam device, a range between a minimum value and a maximum value of the second actuating parameter, where the minimum value and a maximum value of the second actuating parameter depend on a magnification of the beam device.

In an embodiment of the method according to the system described herein, it is additionally or alternatively provided that an additional control parameter is used to generate the information about the object. In particular, the above-mentioned generated information about the object is a first information about the object. The method according to the system described herein further includes determining, using the processing unit, whether the first information about the object fulfils a desired quality standard. The desired quality standard may be given by a user or may be determined as outlined further elsewhere herein. If the desired quality standard is not fulfilled, the following steps of the method according to the system described herein are carried out:
(a) obtaining, using the processing unit, third data from the database being connected to the processing unit. The third data includes the object data about the object, the data about the plurality of machine learning models as well as third range data about a range of possible values of at least a third control parameter used to control the control unit of the beam device. The third control parameter may be any control parameter used to control the control unit of the beam device, for example at least one of the control parameters as mentioned elsewhere herein;
(b) determining, using the processing unit, a third machine learning model of the plurality of machine learning models based on the third data. Determining the third machine learning model may additionally be based on the determined control value of the first control parameter and/or the determined control value of the second control parameter. The third machine learning model may be one of the machine learning models mentioned elsewhere herein;
(c) providing the object data and the third range data as input data to the third machine learning model;
(d) determining, using the third machine learning model, a control value of the third control parameter, where the control value of the third control parameter is an output of the third machine learning model;
(e) using the determined control value of the third control parameter to operate the control unit; and
(f) generating, using the beam device and the control unit of the beam device, second information about the object.

Therefore, the second information may be generated by using the determined control value of the first control parameter, by using the determined control value of the second control parameter and/or by using the determined control value of the third control parameter to operate the control unit.

In an embodiment of the method according to the system described herein, it is additionally or alternatively provided that generating the second information about the object includes generating an image of the object. For example, the image of the object is generated using a light microscope, a laser beam device and/or a particle beam device. Additionally or alternatively, generating the second information about the object includes generating a spectroscopy analysis about the object. For example, interaction radiation of an interaction between the beam of the beam device and the object is detected using a detector. The interaction radiation may be x-ray radiation or cathodoluminescent light. By way of example, a radiation detector is used to detect the interaction radiation. Further examples are discussed further below.

In an embodiment of the method according to the system described herein, it is additionally or alternatively provided that the method includes at least one of the following:
(i) using a light microscope as the beam device;
(ii) using a laser beam device as the beam device;
(iii) using a particle beam device as the beam device;
(iv) using an electron beam device as the beam device; and
(v) using an ion beam device as the beam device.

The particle beam device may include at least one beam generator that generates a particle beam with charged particles. By way of example, the charged particles are electrons and/or ions. Further, the particle beam device may include at least one guide unit that guides the particle beam onto the object. A guide unit is understood to mean any unit that guides the particle beam onto the object, but also units that shape the particle beam which is then guided to the object. By way of example, the guide unit is embodied as an objective lens to focus the particle beam onto the object, as an electrostatic and/or magnetic unit for beam shaping or for beam guidance, as a stigmator, as a condenser lens or as a mechanically adjustable aperture unit which delimits the particle beam. The charged particles may have a landing energy when the charged particles are incident on the object. Expressed differently, the landing energy of the charged particles is the energy with which the object is examined and/or imaged. The landing energy of the charged particles may differ from the energy with which the charged particles are guided through a beam column of the particle beam device. In particular, provision is made for initially accelerating the charged particles very strongly and only decelerating the latter to the landing energy just before incidence on the object. By way of example, the landing energy of the charged particles lies in the range between 1 eV and 30 keV.

The particle beam device may also include at least one control unit that sets the guide unit by selecting at least one control parameter of the control unit. By way of example, the control parameter is a physical variable, in particular a control current or a control voltage, but also, for example, the ratio of physical variables, in particular an amplification of physical variables. The values of the physical variables are adjustable at the control unit or using the control unit and the control and/or feed the guide unit of the particle beam device in such a way that desired physical effects, for example, the generation of specific magnetic fields and/or electrostatic fields, are brought about.

Moreover, the particle beam device may include at least one detector that detects interaction particles and/or interaction radiation which emerges/emerge from an interaction between the particle beam and the object when the particle beam is incident on the object. By way of example, the interaction particles are secondary particles emitted by the object, for example secondary electrons, particles scattered back at the object, which are also referred to as backscattered particles, and/or scattered particles which, for example, are transmitted through the object in the beam direction. By way of example, the backscattered particles are backscattered electrons. By way of example, the interaction radiation is x-ray radiation or cathodoluminescent light. By way of example, a radiation detector is used to detect the interaction radiation.

Further, the particle beam device may include at least one display unit to display an image of the object and/or a representation of data about the object, where the image and/or the representation is/are generated using detection signals which are generated by detecting the interaction particles and/or interaction radiation.

The embodiments of the invention described herein are not limited to the explained sequence of method steps. The invention also includes different sequences of the method steps which are suitable to achieve the object of the invention. Additionally or alternatively, a parallel execution of at least two method steps is also provided in the method according to the invention. Furthermore, the embodiments of the method according to the invention described herein are not limited to the entirety of all method steps mentioned elsewhere herein. In particular, it is intended that in further embodiments individual or several of the method steps mentioned herein are omitted.

The system described herein also relates to a computer program product that includes a program code which is loadable or which is loaded into a processor of a beam device. The program code, when executed by the processor, controls the beam device to carry out a method having at least one of the features described herein or a combination of at least two of the features described herein. In other words, the system described herein also relates to a non-volatile and computer-readable medium having software which is loadable or is loaded into a processor of a beam device. The software, when executed by the processor, controls the beam device in such a way that a method having at least one of the features described herein or having a combination of at least two of the features described herein is carried out. The software includes executable code that performs at least one of the method steps explained herein.

Therefore, the system described herein also relates to a processor being configured to carry out a method having at least one of the features described herein or a combination of at least two of the features described herein.

The system described herein further relates to a beam device, explained elsewhere herein, that generates information about an object, as summarized below. The beam device according to the system described herein includes at least one beam generator that generates a beam, at least one objective lens that focuses the beam onto the object, at least one detector unit that detects interaction particles and/or interaction radiation resulting from an interaction of the beam with the object, and at least one processor in which a computer program product having the features described herein is loaded.

In an embodiment of the beam device according to the system described herein, the beam device additionally or alternatively includes (a) a light microscope that images and/or analyzes the object and/or (b) a laser beam device that images, processes and/or analyzes the object.

In an embodiment of the beam device according to the system described herein, the beam device additionally or alternatively includes a particle beam device that images, processes and/or analyzes the object. For example, the beam generator is a particle beam generator that generates a particle beam with charged particles. The charged particles may be electrons and/or ions. Furthermore, the objective lens may be an objective lens that focuses the particle beam onto the object and the detector unit may be a detector unit that detects interaction particles and/or interaction radiation resulting from the interaction of the particle beam with the object. Furthermore, the particle beam device may include at least one scanning device that scans the particle beam over the object.

In yet another embodiment of the particle beam device according to the system described herein, it is additionally or alternatively provided that the particle beam generator is a first particle beam generator and that the particle beam is a first particle beam having first charged particles. The objective lens is a first objective lens that focuses the first particle beam onto the object. Furthermore, the particle beam device according to the system described herein includes at least one second beam generator that generates a second particle beam with second charged particles. Furthermore, the particle beam device according to the system described herein includes at least one second objective lens that focuses the second particle beam onto the object.

In particular, it is provided that the beam device according to the system described herein is configured as an electron beam device and/or as an ion beam device.

The system described herein also relates to a computer-implemented method that generates a training dataset for (a) a processing unit associated with a beam device and/or (b) a machine learning model that determines a control value of a first control parameter to operate a control unit of a beam device and a control value of a second control parameter to operate the control unit of the beam device. The training dataset is used to train the processing unit and/or the machine learning model. The computer-implemented method includes determining the control value of the first control parameter using the method that includes at least one of the features described herein or a combination of at least two of the features described herein. Additionally, the computer-implemented method includes determining the control value of the second control parameter using the method having at least one of the features described herein or a combination of at least two of the features described herein. Furthermore, the computer-implemented method includes generating, using the beam device and the control unit of the beam device, the information about the object, where the control unit is controlled using the determined control value of the first control parameter and the determined control value of the second control parameter. Furthermore, the computer-implemented method includes storing the determined control value of the first control parameter, the determined control value of the second control parameter and the generated information about the object in a database as the training dataset. This training dataset may be used to train the processing unit and/or the machine learning model.

All of the above and following embodiments of the computer-implemented method according to the invention are not limited to the explained sequence of method steps. The invention also includes different sequences of the method steps which are suitable to achieve the object of the invention. Additionally or alternatively, a parallel execution of at least two method steps is also provided in the computer-implemented method according to the invention. Furthermore, the embodiments described herein of the computer-implemented method according to the invention are not limited to the entirety of all method steps mentioned herein. In particular, it is intended that in further embodiments individual or several of the method steps mentioned herein are omitted.

The system described herein also relates to a further method for training a machine learning model of a beam device to identify an image of an object which fulfils quality standards given by a user. The further method may be a computer-implemented method. This further method is used for training the machine learning model. The beam device may be any beam device as mentioned elsewhere herein. The further method includes the following:
providing, by a user of the beam device, a first image of the object using the beam device, where the first image fulfils the quality standards. For example, image quality may be determined on the basis of subjective criteria. Here, the user determines individually as to whether or not an obtained image quality is sufficient. Alternatively, the image quality of an image of an object may also be determined on the basis of the signal-to-noise ratio of the detector signal. The image quality is not sufficiently good in the case of a signal-to-noise ratio in the range from 0 to 5. By way of example, a signal-to-noise ratio in the range from 20 to 40 is determined to be good (and hence also a good and sufficient image quality). The direction of a secondary particle beam may also be a measure for the image quality. The secondary electrons may be emitted from the object at different solid angles. Further, the backscattered electrons may be backscattered into different solid angles at the object. The direction of the secondary particle beam (i.e., the solid angles along which the secondary particle beam extends) may be influenced by tilting the primary electron beam and/or the object in relation to the optical axis of the electron beam device. As a result of this, it is possible, on the one hand, to select the direction of the secondary particle beam in such a way that the secondary particle beam is incident on a desired detector. On the other hand, it is possible to influence both the number of the generated secondary electrons and the number of the backscattered electrons by way of the aforementioned tilting. By way of example, if the primary electron beam is incident into the object parallel to a crystal lattice of an object, the number of secondary electrons and/or backscattered electrons reduces. The detection signal becomes weaker, leading to reduction in the image quality. It is possible to increase the number of secondary electrons and number of backscattered electrons by setting the tilt of the primary electron beam. Using such a setting, it is possible to differentiate crystals with a first orientation from crystals with a second orientation on the basis of the strength of the detection signal. As mentioned above, it is also possible to detect interaction radiation, for example cathodoluminescent light and x-ray radiation;
providing at least a first deteriorated image by deteriorating the first image using a processing unit associated with the beam device and providing at least a second deteriorated image by deteriorating the first image using the processing unit associated with the beam device;
evaluating, by the user, whether the at least one first deteriorated image fulfils the quality standards and labeling the at least one first deteriorated image depending on evaluating the at least one first deteriorated image;
evaluating, by the user, whether the at least one second deteriorated image fulfils the quality standards and labeling the at least one second deteriorated image depending on evaluating the at least one second deteriorated image;
simulating, using the machine learning model, evaluating the at least one first deteriorated image and evaluating the at least one second deteriorated image, where the first image, the at least one first deteriorated image and the at least one second deteriorated image are used as training data for the machine learning model and simulating is based on the first image, the at least one first deteriorated image and the at least one second deteriorated image;
optionally providing, by the user of the beam device, a second image of an object using the beam device, where the second image fulfils the quality standards;
providing at least a third deteriorated image by deteriorating the first image and/or the second image using the processing unit associated with the beam device and providing at least a fourth deteriorated image by deteriorating the first image and/or the second image using the processing unit associated with the beam device;
evaluating, using the machine learning model, whether the at least one third deteriorated image fulfils the quality standards and labeling the at least one third deteriorated image depending on evaluating the at least one third deteriorated image, where evaluating and labeling the at least one third deteriorated image are repeated, until it is verified, using the processing unit associated with the beam device, whether the labeling is correctly done;
evaluating, using the machine learning model, whether the at least one fourth deteriorated image fulfils the quality standards and labeling the at least one fourth deteriorated image depending on evaluating the at least one fourth deteriorated image, where evaluating and labeling the at least one fourth deteriorated image are repeated, until it is verified, using the processing unit associated with the beam device, whether the labeling is correctly done;
providing, by the user and/or the processing unit associated with the beam device, at least one third image of the object; and
evaluating, using the machine learning model, whether the at least one third image fulfils the quality standards and labeling the at least one third image depending on evaluating the at least one third image, where evaluating and labeling the at least one third image are repeated, until it is verified, using the processing unit, whether the labeling is correctly done.

After the machine learning model has been trained using the further method, the machine learning model is able to identify whether an image of an object fulfils provided quality standards without having to input any further reference images into the machine learning model.

All of the embodiments described herein of the further method according to the invention are not limited to the explained sequence of method steps. The invention also includes different sequences of the method steps which are suitable to achieve the object of the invention. Additionally or alternatively, a parallel execution of at least two method steps is also provided in the further method according to the invention. Furthermore, the embodiments described herein of the further method according to the invention are not limited to the entirety of all method steps mentioned herein. In particular, it is intended that in further embodiments individual or several of the method steps mentioned herein are omitted.

### BRIEF DESCRIPTION OF DRAWINGS

Further practical embodiments and advantages of the system described herein are described below in connection with the following figures:

FIG. 1 shows a first embodiment of a beam device according to the system described herein;

FIG. 2 shows a second embodiment of a beam device according to the system described herein;

FIG. 3 shows a third embodiment of a beam device according to the system described herein;

FIG. 4 shows a schematic representation of an operating system used to operate a beam device according to the system described herein;

FIG. 5 shows a schematic representation of the machine learning model according to the system described herein;

FIG. 6 schematically shows a flowchart of an embodiment of the method used to operate a beam device according to the system described herein;

FIG. 7 schematically shows a flowchart of a further embodiment of the method used to operate a beam device according to the system described herein;

FIG. 8 schematically shows a flowchart of a method for generating a training dataset for a processing unit associated with a beam device and/or a machine learning model according to the system described herein; and

FIG. 9 schematically shows a flowchart of a method for training a machine learning model used for a beam device according to the system described herein.

### DESCRIPTION OF VARIOUS EMBODIMENTS

The system described herein will now be explained in more detail using a beam device in the form of an SEM and in the form of a combination device that includes an electron beam column and an ion beam column. It is expressly noted that the invention can be used with any beam device, in particular with any light microscope, laser beam device and/or particle beam device.

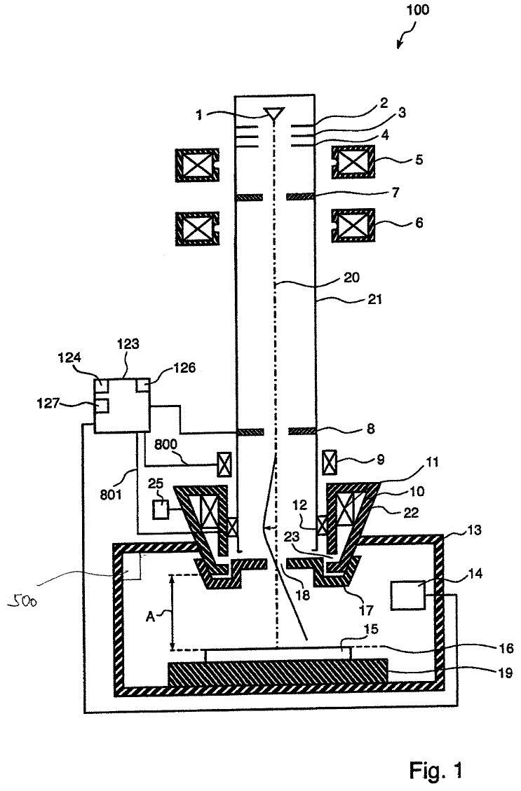

FIG. 1 shows a schematic representation of a first embodiment of a particle beam device according to the system described herein in the form of an SEM 100. The SEM 100 has a beam generator 1 with an electron source, an extraction electrode 2, a control electrode 3 and an anode 4. The anode 4 forms a source-side end of a beam-guiding tube 21 of the SEM 100. The beam generator 1 is configured, for example, as a thermal field emitter. Alternatively, the beam generator 1 is configured, for example, as a thermal tungsten emitter or as an LaB₆ emitter.

Electrons emitted from the beam generator 1 form a primary electron beam. The electrons are accelerated to anode potential due to a potential difference between the beam generator 1 and the anode 4. For example, the potential of the anode 4 is 1 kV to 30 kV positive with respect to the potential of the beam generator 1 such that the electrons have a kinetic energy in the range between 1 keV and 30 keV.

Starting from the anode 4 and viewed in the direction of an objective lens 10 along an optical axis 20, the SEM 100 has first a first condenser lens 5 and then a second condenser lens 6. An aperture unit 7 is arranged in the beam-guiding tube 21 between the first condenser lens 5 and the second condenser lens 6. In the SEM 100 shown in FIG. 1, the objective lens 10 is configured as a magnetic lens having a pole piece 22 with a pole piece gap 23. An annular coil 11 is arranged in the pole piece 22 to generate a magnetic field of the objective lens 10.

Starting from the second condenser lens 6 and viewed in the direction of the objective lens 10, a guiding device in the form of a deflection device having a first guiding device in the form of a first deflection device 9 and a second guiding device in the form of a second deflection device 12 is arranged along the optical axis 20 of the SEM 100. The first deflection device 9 is arranged on the source side of the objective lens 10. The second deflection device 12, on the other hand, is arranged on the object side inside the objective lens 10 on the beam guiding tube 21. The first deflection device 9 and the second deflection device 12 are crossed deflection devices. In other words, both the first deflection device 9 and the second deflection device 12 are configured to deflect the primary electron beam in two non-parallel directions aligned perpendicularly to the direction of the optical axis 20. For example, the first deflection device 9 and/or the second deflection device 12 are/is (a) magnetic deflection device(s). In particular, the first deflection device 9 and/or the second deflection device 12 have/has, for example, four air coils arranged around the optical axis 20 of the SEM 100. Additionally or alternatively, the first deflection device 9 and/or the second deflection device 12 are/is (a) electrostatic deflection device(s). In particular, the first deflection device 9 and/or the second deflection device 12 have/has, for example, four electrodes arranged around the optical axis 20 of the SEM 100, to which different electrostatic potentials can be applied.

The objective lens 10 is arranged on an object chamber 13. In particular, the objective lens 10 projects through an opening of the object chamber 13 into an interior space of the object chamber 13. A movable object stage 19 is arranged in the interior space of the object chamber 13. An object 15 can be arranged on the object stage 19.

Using the objective lens 10, the primary electron beam generated by the beam generator 1 and formed using the first condenser lens 5 and/or the second condenser lens 6 is focused in an object plane 16. Suitable excitations of the first deflection device 9 and the second deflection device 12 ensure that the primary electron beam may be deflected in the object plane 16 perpendicularly to the optical axis 20 of the SEM 100 in such a way that the surface of the object 15 arranged in the object plane 16 can be scanned by different deflections of the primary electron beam. The electrons of the primary electron beam interact with the object 15. As a result of the interaction, electrons are emitted from the object 15 (so-called secondary electrons) and electrons of the primary electron beam are scattered back (so-called backscattered electrons). The secondary electrons and the backscattered electrons are detected and are used for image generation. An image of the object 15 to be examined is thus obtained. Furthermore, interaction radiation is generated during the interaction, for example X-rays or cathodoluminescent light, which is detected and is subsequently evaluated for analysis of the object 15.

For the detection of the aforementioned interaction particles and/or aforementioned interaction radiation, for example, a first detector unit 14 is arranged in the object chamber 13. Additionally or alternatively, a second detector unit 8 that detects the aforementioned interaction particles is arranged in the area between the first deflection device 9 and the second condenser lens 6 in the beam guiding tube 21, for example. A radiation detector 500 is arranged at the object chamber 13 to detect interaction radiation (for example X-rays and/or cathodoluminescent light) generated when the primary electron beam impinges on the object 15.

In the embodiment of the SEM 100 shown in FIG. 1, a pressure stage aperture holder 17 is provided which may be arranged on the pole piece 22 of the objective lens 10 projecting into the object chamber 13. The pressure stage aperture holder 17 has a pressure stage aperture with an aperture 18. Further pressure stage aperture units (not shown in FIG. 1) may be arranged, for example, within the beam guiding tube 21 of the SEM 100. Vacuum pumps desired to generate and maintain the vacuum within the beam-guiding tube 21 and the object chamber 13 and desired for operation of the SEM 100 are also not shown in FIG. 1.

If the SEM 100 is operated under high vacuum in the object chamber 13, the pressure stage aperture holder 17 is not essential and accordingly may be removed from the pole piece 22 of the objective lens 10. If, on the other hand, the SEM 100 is operated at relatively high pressure in the object chamber 13 (pressures in the range of about 1 to 3000 Pa), the pressure stage aperture holder 17 may be mounted on the pole piece 22 of the objective lens 10 such that a sufficiently good vacuum may be maintained within the beam-guiding tube 21 by differential pumping despite the higher pressure in the object chamber 13.

In particular, the first detector unit 14, the second detector unit 8, the first deflection device 9 and the second deflection device 12 are connected to a control device 123, which includes a monitor 124. In particular, the first deflection device 9 is connected to the control device 123 by a first signal connection 800. The first signal connection 800 may be a physical connection, for example a connection line, and/or a wireless connection, for example a radio communication system and/or a wireless local area network. The second deflection device 12 is connected to the control device 123 by a second signal connection 801. The second signal connection 801 may be a physical connection, for example a connection line, and/or a wireless connection, for example a radio communication system and/or a wireless local area network. The control device 123 processes detection signals generated by the first detector unit 14 as well as by the second detector unit 8 and displays the detection signals in the form of images on the monitor 124. The control device 123 further includes a database 126 in which data is stored and from which data is read. In addition, the control device 123 is connected to further units of the SEM 100, which is not shown further in FIG. 1.

The control device 123 of the SEM 100 includes a processor 127. A computer program product that includes a program code is loaded into the processor 127. The program code, when executed, carries out a method for operating the SEM 100. This is explained in more detail below.

In the SEM 100, it is possible to set a distance A using the control device 123 of the SEM 100. The distance A is given either (a) by an object distance between an outer boundary of the objective lens 10 of the SEM 100 and the object 15, or (b) by a focal plane distance between the outer boundary of the objective lens 10 of the SEM 100 and a focal plane of the objective lens 10. The aforementioned distance A according to case (a) or case (b) is also referred to as the working distance. For example, the distance A in case (a) is set by moving the object stage 19 and/or moving the objective lens 10 with a moving device 25. In particular, the distance A in case (b) is adjusted by varying an excitation of the objective lens 10 along the optical axis 20 of the SEM 100.

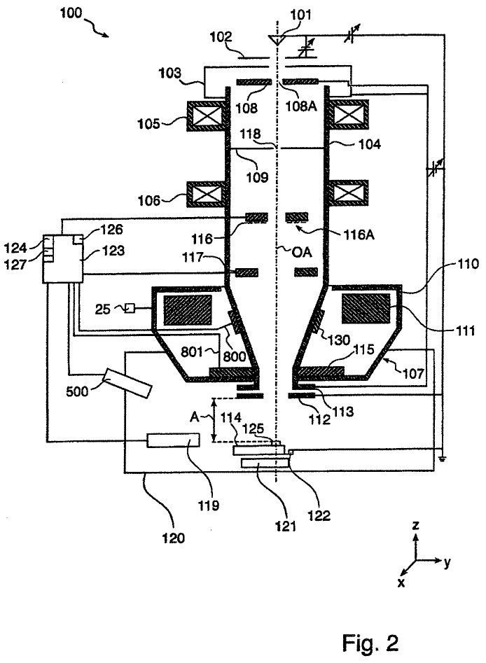

FIG. 2 shows a schematic representation of a further SEM 100. The further SEM 100 has a first beam generator in the form of an electron source 101, which is configured as a cathode. Furthermore, the further SEM 100 is provided with an extraction electrode 102 as well as with an anode 103, which is placed on one end of a beam-guiding tube 104 of the further SEM 100. For example, the electron source 101 is configured as a thermal field emitter. However, the invention is not limited to such an electron source 101. Rather, any electron source suitable for the invention can be used.

Electrons emitted from the electron source 101 form a primary electron beam. The electrons are accelerated to anode potential due to a potential difference between the electron source 101 and the anode 103. In the embodiment shown, the anode potential is 100 V to 35 kV with respect to a ground potential of a housing of an object chamber 120, for example 5 kV to 15 kV, in particular 8 kV. However, the anode potential could alternatively be at ground potential.

Two condenser lenses are arranged on the beam-guiding tube 104, namely a first condenser lens 105 and a second condenser lens 106. Starting from the electron source 101 and viewed in the direction of a first objective lens 107, the first condenser lens 105 is arranged first, followed by the second condenser lens 106. It is explicitly noted that further embodiments of the further SEM 100 may have a single condenser lens only. A first aperture unit 108 is arranged between the anode 103 and the first condenser lens 105. Together with the anode 103 and the beam-guiding tube 104, the first aperture unit 108 is at high voltage potential, namely the potential of the anode 103 or at ground. The first aperture unit 108 has numerous first apertures 108A, one of which is shown in FIG. 2. For example, there are two first apertures 108A. Each of the plurality of first apertures 108A has a different aperture diameter. Using an adjustment mechanism (not shown), it is possible to adjust a desired first aperture 108A to an optical axis OA of the further SEM 100. It is explicitly noted that the first aperture unit 108 of further embodiments may be provided with a single first aperture 108A only. In the embodiment of FIG. 2, an adjustment mechanism may not be provided, and the first aperture unit 108 is configured in a stationary manner. A stationary second aperture unit 109 is arranged between the first condenser lens 105 and the second condenser lens 106. Alternatively, the second aperture unit 109 may be movable.

The first objective lens 107 has pole pieces 110 having a bore. The beam-guiding tube 104 is guided through the bore of the pole pieces 110. A coil 111 is arranged in the pole pieces 110.

An electrostatic deceleration system is arranged in a lower region of the beam-guiding tube 104. The electrostatic deceleration system has a single electrode 112 and a tubular electrode 113. The tubular electrode 113 is arranged at an end of the beam-guiding tube 104 facing an object 125 being arranged at a movable object holder 114.

Together with the beam-guiding tube 104, the tubular electrode 113 is at the potential of the anode 103, while the single electrode 112 and the object 125 are at a potential lower than the potential of the anode 103. In the present case, the potential lower than the potential of the anode 103 is the ground potential of the housing of the object chamber 120. In this way, the electrons of the primary electron beam can be decelerated to an energy which is desired for the examination of the object 125.

The object 125 and the single electrode 112 may also be at different potentials and at different potentials than the ground potential. This makes it possible to adjust the location of the deceleration of the primary electron beam with respect to the object 125. For example, if the deceleration is performed quite close to the object 125, imaging errors become smaller.

The further SEM 100 also includes a guiding system in the form of a deflection device having a first guiding device in the form of a first deflection device 130 and having a second guiding device in the form of a second deflection device 115. The first deflection device 130 is arranged on the source side within the first objective lens 107. On the other hand, the second deflection device 115 is arranged on the object side within the first objective lens 107 on the beam-guiding tube 104. The first deflection device 130 and the second deflection device 115 are crossed deflection devices. In other words, both the first deflection device 130 and the second deflection device 115 are configured to deflect the primary electron beam in two non-parallel directions aligned perpendicularly to the direction of the optical axis OA of the further SEM 100. For example, the first deflection device 130 and/or the second deflection device 115 are/is (a) magnetic deflection device(s). In particular, the first deflection device 130 and/or the second deflection device 115 have/has, for example, four air coils arranged around the optical axis OA of the further SEM 100. Additionally or alternatively, it is provided that the first deflection device 130 and/or the second deflection device 115 are/is (an) electrostatic deflection device(s). In particular, the first deflection device 130 and/or the second deflection device 115 have/has, for example, four electrodes arranged around the optical axis OA of the SEM 100, to which different electrostatic potentials can be applied. Using the first deflection device 130 and the second deflection device 115, the primary electron beam is deflected and can be scanned over the object 125. The electrons of the primary electron beam interact with the object 125. As a result of the interaction, interaction particles are generated, which interaction particles are detected. In particular, electrons are emitted from the surface of the object 125 as interaction particles—so-called secondary electrons—or electrons of the primary electron beam are scattered back—so-called backscattered electrons.

A detector system is arranged in the beam-guiding tube 104, which detector system includes a first detector 116 and a second detector 117 that detect the secondary electrons and/or the backscattered electrons. The first detector 116 is arranged along the optical axis OA on the source side, while the second detector 117 is arranged along the optical axis OA on the object side in the beam-guiding tube 104. The first detector 116 and the second detector 117 are offset from each other in the direction of the optical axis OA of the SEM 100. Both the first detector 116 and the second detector 117 have an opening through which the primary electron beam may pass. The first detector 116 and the second detector 117 are approximately at the potential of the anode 103 and of the beam-guiding tube 104, and the optical axis OA of the SEM 100 passes through the respective opening.

The second detector 117 is primarily used to detect secondary electrons. The secondary electrons initially have a low kinetic energy and arbitrary directions of motion as the secondary electrons emerge the object 125. Due to the strong extraction field emanating from the tubular electrode 113, the secondary electrons are accelerated toward the first objective lens 107. The secondary electrons enter the first objective lens 107 in an approximately parallel manner. The beam diameter of the secondary electrons remains small in the first objective lens 107. The first objective lens 107 acts strongly on the secondary electrons, generating a comparatively short focus of secondary electrons with sufficiently steep angles to the optical axis OA such that the secondary electrons travel apart after the focus and strike the second detector 117 on an active face of the second detector 117. In contrast, electrons backscattered from the object 125—i.e., backscattered electrons that have a relatively high kinetic energy as the backscattered electrons emerge from the object 125 compared to the secondary electrons—are detected by the second detector 117 only to a small extent. The high kinetic energy and the angles of the backscattered electrons with respect to the optical axis OA as the backscattered electrons emerge from the object 125 result in a beam waist, i.e., a beam region of minimum diameter, of the backscattered electrons being located in the vicinity of the second detector 117. A large portion of the backscattered electrons passes through the opening of the second detector 117. Therefore, the first detector 116 is substantially used to detect the backscattered electrons.

In another embodiment of the further SEM 100, the first detector 116 may additionally include a counter field grid 116A. The counter field grid 116A is arranged on the side of the first detector 116 facing the object 125. The counter field grid 116A has a negative potential with respect to the potential of the beam-guiding tube 104 such that only backscattered electrons with a high kinetic energy pass through the counter field grid 116A to the first detector 116. Additionally or alternatively, the second detector 117 includes a further counter field grid which is designed in the same manner as the aforementioned counter field grid 116A of the first detector 116 and which has an analogous function.

Furthermore, the further SEM 100 includes a chamber detector 119 in the object chamber 120, for example an Everhart-Thornley detector or an ion detector, which may include a detection surface coated with metal that shields light.

The detection signals generated by the first detector 116, the second detector 117 and the chamber detector 119 are used to generate an image or images of the surface of the object 125.

It is explicitly noted that the apertures of the first aperture unit 108 and the second aperture unit 109 as well as the openings of the first detector 116 and the second detector 117 are shown in an exaggerated manner. The openings of the first detector 116 and the second detector 117 have an extent perpendicular to the optical axis OA in the range of 0.5 mm to 5 mm. For example, the openings are circular in shape and have a diameter in the range of 1 mm to 3 mm perpendicular to the optical axis OA.

In the embodiment shown in FIG. 2, the second aperture unit 109 is configured as a pinhole aperture unit and is provided with a second aperture 118 for the passage of the primary electron beam. The second aperture 118 has an extension in the range from 5 μm to 500 μm, for example 35 μm. Alternatively, in a further embodiment, the second aperture unit 109 is provided with a plurality of apertures which can be mechanically displaced with respect to the primary electron beam or which can be reached by the primary electron beam using electrical and/or magnetic deflection elements. The second aperture unit 109 may be a pressure stage aperture, which separates a first region, in which the electron source 101 is arranged and in which an ultra-high vacuum prevails (10⁻⁷ hPa to 10⁻¹² hPa), from a second region which has a high vacuum (10⁻³ hPa to 10⁻⁷ hPa). The second region is the intermediate pressure region of the beam-guiding tube 104 which leads to the object chamber 120.

The object chamber 120 is under vacuum. A pump (not shown) is arranged at the object chamber 120 to generate the vacuum. In the embodiment shown in FIG. 2, the object chamber 120 is operated in a first pressure range or in a second pressure range. The first pressure range includes only pressures less than or equal to 10⁻³ hPa, and the second pressure range includes only pressures greater than 10⁻³ hPa. The object chamber 120 is vacuum-sealed to ensure the first pressure range and the second pressure range.

The object holder 114 is arranged on an object stage 122. The object stage 122 is configured to be movable in three mutually perpendicular directions, namely in an x-direction (first stage axis), in a y-direction (second stage axis) and in a z-direction (third stage axis). In addition, the object stage 122 may be rotated about two mutually perpendicularly arranged rotation axes (stage rotation axes). The invention is not limited to the object stage 122 described above. Rather, the object stage 122 may have further translational axes and further rotational axes along or about which the object stage 122 may move.

The further SEM 100 further includes a third detector 121 arranged in the object chamber 120. In particular, the third detector 121 is arranged behind the object stage 122 as viewed from the electron source 101 along the optical axis OA. The object stage 122, and thus the object holder 114, may be rotated such that the primary electron beam may impinge onto the object 125 being arranged on the object holder 114. As the primary electron beam passes through the object 125 to be examined, the electrons of the primary electron beam interact with the material of the object 125 to be examined. The electrons passing through the object 125 to be examined are detected by the third detector 121.

A radiation detector 500 is arranged at the object chamber 120 to detect interaction radiation (for example X-rays and/or cathodoluminescent light) generated when the primary electron beam impinges onto the object 125. The radiation detector 500, the first detector 116, the second detector 117, and the chamber detector 119 are connected to a control device 123 which includes a monitor 124. The third detector 121 is also connected to the control device 123, which is not shown for the sake of clarity. The control device 123 processes detection signals generated by the first detector 116, the second detector 117, the chamber detector 119, the third detector 121 and/or the radiation detector 500 and displays the detection signals in the form of images on the monitor 124.

The first deflection device 130 and the second deflection device 115 are connected to the control device 123. In particular, the first deflection device 130 is connected to the control device 123 by a first signal connection 800. The first signal connection 800 may be a physical connection, for example a connection line, and/or a wireless connection, for example a radio communication system and/or a wireless local area network. The second deflection device 115 is connected to the control device 123 by a second signal connection 801. The second signal connection 801 may be a physical connection, for example a connection line, and/or a wireless connection, for example a radio communication system and/or a wireless local area network.

The control device 123 further includes a database 126 in which data is stored and from which data is read. Furthermore, the control device 123 is connected to further units of the further SEM 100, which is not shown in more detail for reasons of clarity.

The control device 123 of the further SEM 100 includes a processor 127. A computer program product with a program code is loaded into the processor 127. When the program code is executed, a method for operating the further SEM 100 is carried out. This is explained in more detail below.

In the further SEM 100, it is possible to set a distance A using the control device 123 of the further SEM 100. The distance A is given either (a) by an object distance between the single electrode 112 of the further SEM 100 and the object 125, or (b) by a focal plane distance between the single electrode 112 of the further SEM 100 and a focal plane of the first objective lens 107. The aforementioned distance A according to case (a) or case (b) is also referred to as the working distance. For example, the distance A in case (a) is set by moving the object stage 122 and/or moving the first objective lens 107 with a moving device 25. For example, in case (b), the distance A is set by varying an excitation of the first objective lens 107 along the optical axis OA of the further SEM 100.

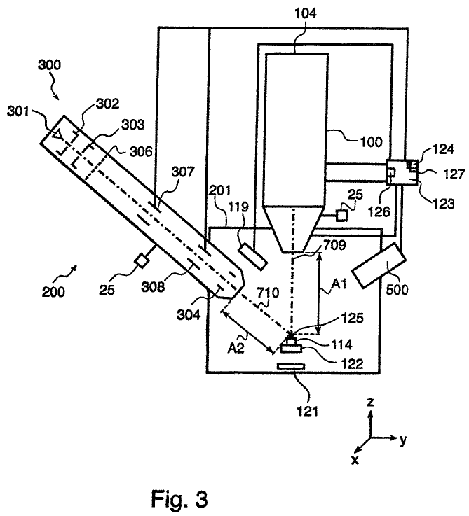

FIG. 3 shows a particle beam device in the form of a combination device 200. The combination device 200 has two particle beam columns. On the one hand, the combination device 200 has the further SEM 100 as shown in FIG. 2, but without the object chamber 120. Rather, the further SEM 100 is arranged at an object chamber 201. The object chamber 201 is under vacuum. A pump (not shown) is arranged at the object chamber 201 to generate the vacuum. In the embodiment shown in FIG. 3, the object chamber 201 is operated in a first pressure range or in a second pressure range. The first pressure range includes only pressures less than or equal to 10⁻³ hPa, and the second pressure range includes only pressures greater than 10⁻³ hPa. The object chamber 201 is vacuum-sealed to ensure the first and the second pressure ranges.

The chamber detector 119 is arranged in the object chamber 201. The chamber detector 119 is configured, for example, as an Everhart-Thornley detector or as an ion detector. The chamber detector 119 may have a detection surface coated with metal that shields light. Furthermore, the third detector 121 is arranged in the object chamber 201.

The further SEM 100 generates a first particle beam, namely the primary electron beam described above, and has the optical axis mentioned above, which optical axis is provided with the reference sign 709 in FIG. 3 and which is referred to hereinafter as the first beam axis. Secondly, the combination device 200 is provided with an ion beam device 300 which is also arranged at the object chamber 201. The ion beam device 300 also has an optical axis which is provided with the reference sign 710 in FIG. 3 and which is referred to hereinafter as the second beam axis.

The further SEM 100 is arranged vertically with respect to the object chamber 201. In contrast, the ion beam device 300 is arranged in an inclined manner to the further SEM 100 by an angle of about 0° to 90°. In FIG. 3, an arrangement of about 50° is shown. The ion beam device 300 includes a second beam generator in the form of an ion beam generator 301. The ion beam generator 301 is used to generate ions that form a second particle beam in the form of an ion beam. The ions are accelerated using an extraction electrode 302 which is at a predeterminable potential. The second particle beam then passes through ion optics of the ion beam device 300, the ion optics including a condenser lens 303 and a second objective lens 304. Finally, the second objective lens 304 generates an ion probe that is focused on the object 125 arranged on an object holder 114. The object holder 114 is arranged on an object stage 122.

An adjustable or selectable aperture unit 306 and a guiding system are arranged above the second objective lens 304 (i.e., in the direction of the ion beam generator 301). The guiding system includes a first guiding device in the form of a first deflection device 307 and a second guiding device in the form of a second deflection device 308. The first deflection device 307 is arranged on the source side within the second objective lens 304. On the other hand, the second deflection device 308 is arranged inside the second objective lens 304 on the object side. The first deflection device 307 and the second deflection device 308 are crossed deflection devices. In other words, both the first deflection device 307 and the second deflection device 308 are configured to deflect the ion beam in two non-parallel directions aligned perpendicularly to the direction of the optical axis in the form of the second beam axis 710 of the ion beam device 300. For example, the first deflection device 307 and/or the second deflection device 308 are/is (a) magnetic deflection device(s). In particular, the first deflection device 307 and/or the second deflection device 308 may have, for example, four air coils arranged around the optical axis in the form of the second beam axis 710 of the ion beam device 300. Additionally or alternatively, the first deflection device 307 and/or the second deflection device 308 are/is (an) electrostatic deflection device(s). In particular, the first deflection device 307 and/or the second deflection device 308 may have, for example, four electrodes arranged around the optical axis in the form of the second beam axis 710 of the ion beam device 300, to which electrodes different electrostatic potentials may be applied. Using the first deflection device 307 and the second deflection device 308, the ion beam is deflected and may be scanned over the object 125.

As explained above, the object holder 114 is arranged on the object stage 122. In the embodiment shown in FIG. 3, the object stage 122 is configured to move in three mutually perpendicular directions, namely in an x-direction (first stage axis), in a y-direction (second stage axis), and in a z-direction (third stage axis). Furthermore, the object stage 122 may be rotated about two rotation axes arranged perpendicularly to each other (stage rotation axes).

The distances between the individual units of the combination device 200 shown in FIG. 3 are shown in an exaggerated manner to better represent the individual units of the combination device 200.

A radiation detector 500 is arranged at the object chamber 201 to detect interaction radiation, for example X-rays and/or cathodoluminescent light. The radiation detector 500 is connected to a control device 123 which includes a monitor 124.

The control device 123 processes detection signals generated by the first detector 116 (not shown in FIG. 3), the second detector 117 (not shown in FIG. 3), the chamber detector 119, the third detector 121 and/or the radiation detector 500 and displays the detection signals in the form of images on the monitor 124.

The control device 123 further includes a database 126 in which data is stored and from which data is read. Further, the control device 123 is connected to the first deflection device 130 by the first signal connection 800 (not shown in FIG. 3) and to the second deflection device 115 by the second signal connection 801 (not shown in FIG. 3). Additionally, the control device 123 is connected to the first deflection device 307 by a first signal connection and to the second deflection device 308 by a second signal connection. Furthermore, the control device 123 is connected to further units of the combination device 200 which is not shown in FIG. 3 for the sake of clarity.

The control device 123 of the combination device 200 includes a processor 127. A computer program product having program code is loaded into the processor 127. When executing the program code, a method for operating the combination device 200 is carried out. This is explained in more detail below.

It is also possible to set working distances in the combination device 200. For example, in the further SEM 100, it is possible to set a distance A1 using the control device 123. The distance A1 is given either (a) by an object distance between an outer boundary of the first objective lens 107 of the further SEM 100 and the object 125, or (b) by a focal plane distance between the outer boundary of the first objective lens 107 of the further SEM 100 and a focal plane of the first objective lens 107. The aforementioned distance A1 according to case (a) or case (b) is also referred to as the working distance. For example, the distance A1 in case (a) is set by moving the object stage 122 and/or moving the first objective lens 107 with the moving device 25. For example, in case (b), the distance A1 is adjusted by varying an excitation of the first objective lens 107 along the first beam axis 709 of the further SEM 100. Further, it is possible to adjust a distance A2 using the control device 123. The distance A2 is given by either (a) an object distance between an outer boundary of the second objective lens 304 of the ion beam device 300 and the object 125, or (b) a focal plane distance between the outer boundary of the second objective lens 304 of the ion beam device 300 and a focal plane of the second objective lens 304. The aforementioned distance A2 according to case (a) or case (b) is also referred to as the working distance. For example, the distance A2 in case (a) is set by moving the object stage 122 and/or moving the second objective lens 304 with a moving device 25. For example, in case (b), the distance A2 is adjusted by varying an excitation of the second objective lens 304 along the second beam axis 710 of the ion beam device 300.

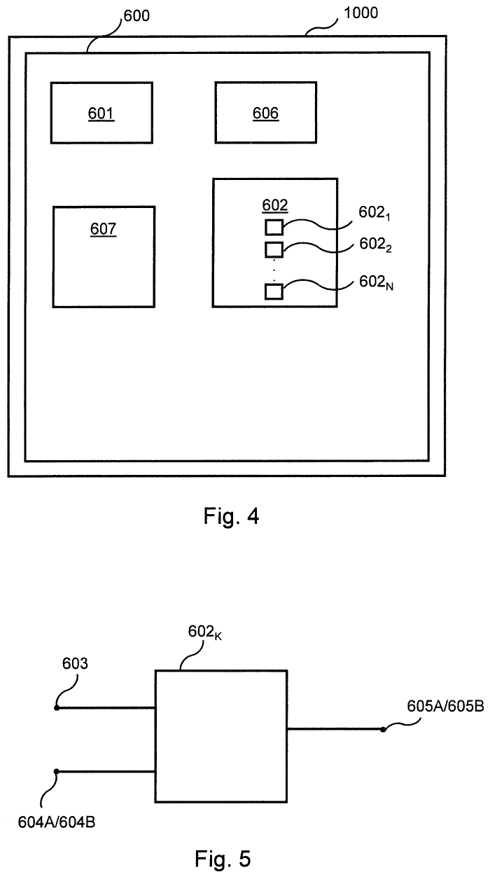

FIG. 4 shows a schematic representation of an operating system 600 used for operating a beam device 1000. The beam device 1000 may be a light microscope, a laser beam device and/or a particle beam device, in particular the SEM 100 of FIG. 1, the further SEM 100 of FIG. 2 and/or the combination device 200 of FIG. 3. The operating system 600 includes a processing unit 601. The processing unit 601 is associated with the beam device 1000. For example, the processing unit 601 may be the processor 127 as discussed further above. Additionally or alternatively, the processing unit 601 may be a unit separated from the beam device 1000, but which is connected to the beam device 1000. The connection between the processing unit 601 and the beam device 1000 may be wireless or by wire.

The operating system 600 also includes a database 606. The database 606 may be a database associated with the beam device 1000. For example, the database 606 may be the database 126 as discussed further above. Additionally or alternatively, the database 606 may be a unit separated from the beam device 1000, but which is connected to the beam device 1000. The connection between the processing unit 601 and the database 606 may be wireless or by wire.

The operating system 600 also includes a control unit 607. At least one control parameter is used to operate the control unit 607. By way of example, the control parameter is a physical variable, in particular a control current or a control voltage, but also, for example, the ratio of physical variables, in particular an amplification of physical variables. The values of the physical variable are adjustable at the control unit 607 and the control and/or feed the units of the beam device 1000 in such a way that desired physical effects, for example, the generation of specific magnetic fields and/or electrostatic fields, are brought about. For example, the control device 123 may be the control unit 607. For example, with respect to the SEM 100 of FIG. 1, the control device 123 is used to control the first deflection device 9 and the second deflection device 12, where the first deflection device 9 and the second deflection device 12 are connected to the control device 123. In particular, the first deflection device 9 is connected to the control device 123 by the first signal connection 800. The first signal connection 800 may be a physical connection, for example a connection line, and/or a wireless connection, for example a radio communication system and/or a wireless local area network. The second deflection device 12 is connected to the control device 123 by the second signal connection 801. The second signal connection 801 may be a physical connection, for example a connection line, and/or a wireless connection, for example a radio communication system and/or a wireless local area network.

The operating system 600 for the beam device 1000 also includes a plurality 602 of machine learning models 602₁ to 602ₙ, where the following applies: 1≤n≤N, where N is an integer. In other words, the plurality 602 of machine learning models 602₁ to 602ₙ may include the heuristic autotuning algorithm, the supervised learning algorithm and/or a reinforcement algorithm. The aforementioned algorithms are known in the art. The algorithms are briefly discussed further above, which also applies here.

FIG. 5 shows a schematic representation of the machine learning model 602ₖ, where k is an integer for which applies: 1≤k≤n. The further machine learning models 602₁ to 602ₙ may have a similar or identical structure.

The machine learning model 602ₖ receives object data 603 as an input. The object data 603 may include specific information about the object 15, 125. For example, the object data 603 may include at least one of the following: (a) information about the material or the materials in the object 15, 125, (b) the size of the object 15, 125 and (c) the temperature of the object 15, 125. The invention is not limited to specifics of the object data 603. Rather, any information about the object 15, 125 which is suitable for the invention may be used for the invention. The machine learning model 602ₖ may also receive first range data 604A and/or second range data 604B as an input. The first range data 604A includes a range of possible values of at least one first control parameter used to control the control unit 607 of the beam device 1000. The second range data 604B includes a range of possible values of at least one second control parameter used to control the control unit 607 of the beam device 1000. Examples of the first control parameter and of the second control parameter are discussed elsewhere herein, which also applies here.

The machine learning model 602ₖ provides a control value 605A of the first control parameter and/or a control value 605B of the second control parameter as an output of the machine learning model 602ₖ. The control value 605A of the first control parameter and/or the control value 605B of the second control parameter are used to operate the control unit 607.

An embodiment of the system described herein includes at least one of the following:
using, as the first control parameter, a first physical variable;
using, as the first control parameter, a first control current or a first control voltage;
using, as the first control parameter, a first ratio of physical variables;
using, as the first control parameter, a first amplification of physical variables;
using, as the second control parameter, a second physical variable;
using, as the second control parameter, a second control current or a second control voltage;
using, as the second control parameter, a second ratio of physical variables; and
using, as the second control parameter, a second amplification of physical variables.

A further embodiment of the system described herein includes using, as the first control parameter, one of the following: a first contrast parameter that sets the contrast of the information about the object 15, 125, a first brightness parameter that sets the brightness of the information about the object 15, 125, a first actuating parameter that serves to actuate an objective lens 10, 107, 304, of the beam device 1000 (for example in the form of the SEM 100 of FIG. 1, in the form of the further SEM 100 of FIG. 2 and/or in the form of the combination device 200 of FIG. 3). Moreover, the first control parameter may be a first setting parameter that serves to set an electrostatic and/or magnetic unit 2, 3, 4, 5, 6, 7, 9, 10, 11, 12, 21, 22, 23, 102, 103, 104, 105, 106, 107, 108, 109, 110, 111, 112, 113, 115, 116A, 130, 302, 303, 304, 306, 307, 308 of the beam device 1000 (for example in the form of the SEM 100 of FIG. 1, in the form of the further SEM 100 of FIG. 2 and/or in the form of the combination device 200 of FIG. 3). Additionally, the first control parameter may be a first controlling parameter that serves to control and set an electrostatic and/or magnetic deflection unit 2, 3, 4, 5, 6, 7, 9, 10, 11, 12, 21, 22, 23, 102, 103, 104, 105, 106, 107, 108, 109, 110, 111, 112, 113, 115, 116A, 130, 302, 303, 304, 306, 307, 308 of the beam device 1000 (for example, in the form of the SEM 100 of FIG. 1, in the form of the further SEM 100 of FIG. 2 and/or in the form of the combination device 200 of FIG. 3) to achieve a shift of the beam of the beam device 1000. Furthermore, the first control parameter may be a first stigmator parameter that sets a stigmator of the beam device 1000 (for example, in the form of the SEM 100 of FIG. 1, in the form of the further SEM 100 of FIG. 2 and/or in the form of the combination device 200 of FIG. 3).

A further embodiment of the system described herein includes using, as the second control parameter, one of the following: a second contrast parameter that sets the contrast of the information about the object 15, 125, a second brightness parameter that sets the brightness of the information about the object 15, 125, a second actuating parameter that serves to actuate an objective lens 10, 107, 304 of the beam device 1000 (for example in the form of the SEM 100 of FIG. 1, in the form of the further SEM 100 of FIG. 2 and/or in the form of the combination device 200 of FIG. 3). Moreover, the second control parameter may be a second setting parameter that serves to set an electrostatic and/or magnetic unit 2, 3, 4, 5, 6, 7, 9, 10, 11, 12, 21, 22, 23, 102, 103, 104, 105, 106, 107, 108, 109, 110, 111, 112, 113, 115, 116A, 130, 302, 303, 304, 306, 307, 308 of the beam device 1000 (for example in the form of the SEM 100 of FIG. 1, in the form of the further SEM 100 of FIG. 2 and/or in the form of the combination device 200 of FIG. 3). Additionally, the second control parameter may be a second controlling parameter that serves to control and set the electrostatic and/or magnetic deflection unit 2, 3, 4, 5, 6, 7, 9, 10, 11, 12, 21, 22, 23, 102, 103, 104, 105, 106, 107, 108, 109, 110, 111, 112, 113, 115, 116A, 130, 302, 303, 304, 306, 307, 308 of the beam device 1000 (for example in the form of the SEM 100 of FIG. 1, in the form of the further SEM 100 of FIG. 2 and/or in the form of the combination device 200 of FIG. 3) to achieve a shift of the beam of the beam device 1000 (for example, in the form of the SEM 100 of FIG. 1, in the form of the further SEM 100 of FIG. 2 and/or in the form of the combination device 200 of FIG. 3). Furthermore, the second control parameter may be a second stigmator parameter that sets a stigmator of the beam device 1000 (for example in the form of the SEM 100 of FIG. 1, in the form of the further SEM 100 of FIG. 2 and/or in the form of the combination device 200 of FIG. 3).

The invention is not restricted to the examples given for the first control parameter and/or the second control parameter. Rather, any control parameter which is suitable for the invention, may be used. Examples of further control parameters are discussed elsewhere herein, which also applies here.

In yet a further embodiment of the system described herein, it is additionally or alternatively provided that the system described herein includes at least one of the following:
using, as the range of possible values of the first control parameter, a range between a minimum value and a maximum value of the first control parameter, where the minimum value and a maximum value of the first control parameter depend on a configuration of the control unit 607;
using, as the range of possible values of the first control parameter configured as a first contrast parameter that sets the contrast of the information about the object 15, 125, a range between a minimum value and a maximum value of the first contrast parameter, where the minimum value and a maximum value of the first contrast parameter depend on a configuration of the control unit 607;
using, as the range of possible values of the first control parameter configured as a first brightness parameter that sets the brightness of the information about the object 15, 125, a range between a minimum value and a maximum value of the first brightness parameter, where the minimum value and a maximum value of the first brightness parameter depend on a configuration of the control unit 607;
using, as the range of possible values of the first control parameter configured as a first actuating parameter that serves to actuate the objective lens 10, 107, 304 of the beam device 1000 (for example in the form of the SEM 100 of FIG. 1, in the form of the further SEM 100 of FIG. 2 and/or in the form of the combination device 200 of FIG. 3), a range between a minimum value and a maximum value of the first actuating parameter, where the minimum value and a maximum value of the first actuating parameter depend on a magnification of the beam device 1000;
using, as the range of possible values of the second control parameter, a range between a minimum value and a maximum value of the second control parameter, where the minimum value and a maximum value of the second control parameter depend on a configuration of the control unit 607;
using, as the range of possible values of the second control parameter configured as a second contrast parameter that sets the contrast of the information about the object 15, 125, a range between a minimum value and a maximum value of the second contrast parameter, where the minimum value and a maximum value of the second contrast parameter depend on a configuration of the control unit 607;
using, as the range of possible values of the second control parameter configured as a second brightness parameter that sets the brightness of the information about the object 15, 125, a range between a minimum value and a maximum value of the second brightness parameter, where the minimum value and a maximum value of the second brightness parameter depend on a configuration of the control unit 607;
using, as the range of possible values of the second control parameter configured as a second actuating parameter that serves to actuate the objective lens 10, 107, 304 of the beam device 1000 (for example in the form of the SEM 100 of FIG. 1, in the form of the further SEM 100 of FIG. 2 and/or in the form of the combination device 200 of FIG. 3), a range between a minimum value and a maximum value of the second actuating parameter, where the minimum value and a maximum value of the second actuating parameter depend on a magnification of the beam device 1000 (for example in the form of the SEM 100 of FIG. 1, in the form of the further SEM 100 of FIG. 2 and/or in the form of the combination device 200 of FIG. 3).

Now, exemplary embodiments of the method for operating the beam device 1000 according to the system described herein, which are used in the SEM 100 of FIG. 1, are described below. Reference is explicitly made to the fact that the exemplary embodiments of the method according to the invention may also be used analogously in any beam device 1000, for example in the further SEM 100 of FIG. 2 or in the combination device 200 of FIG. 3.

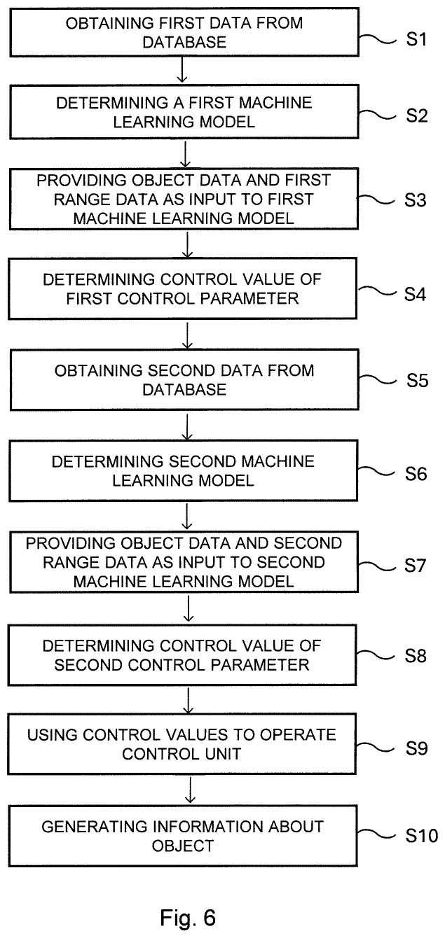

FIG. 6 schematically shows the flowchart of an embodiment of the method used for operating the SEM 100 of FIG. 1.

Method step S1 includes obtaining, using the processing unit 601 which may be the processor 127, first data from the database 606 which may be the database 126. The first data includes object data 603 about the object 15, data about a plurality 602 of machine learning models 602₁ to 602ₙ as well as first range data 604A about a range of possible values of at least one first control parameter used to control the control unit 607 which may be the control device 123 of the SEM 100. The object data may include specific information about the object 15. For example, the object data may include at least one of the following: (a) information about the material or the materials in the object 15, (b) the size of the object 15 and (c) the temperature of the object 15. The invention is not limited to any specific kind of object data 603. Rather, any information about the object 15 which is suitable for the invention may be used for the invention. The first range data 604A includes a range of all possible values of the first control parameter. Examples of the first control parameter are discussed elsewhere herein, which also applies here.

Method step S2 includes determining, using the processing unit 601, a first machine learning model 602ₖ of the plurality 602 of machine learning models 602₁ to 602ₙ based on the first data, where k is an integer for which applies: 1≤k≤n.

Method step S3 includes providing the object data 603 and the first range data 604A as input data to the first machine learning model 602ₖ.

Method step S4 includes determining, using the first machine learning model 602ₖ, a control value 605A of the first control parameter, where the control value 605A of the first control parameter is an output of the first machine learning model 602ₖ. For example, the first machine learning model 602ₖ uses the object data 603 and the first range data 604A to determine the control value 605A of the first control parameter. The control value 605A of the first control parameter is used to provide the information about the object 15 at a later stage of the method according to the system described herein.

Method step S5 includes obtaining, using the processing unit 601, second data from the database 606. The second data includes the object data 603 about the object 15, the data about the plurality 602 of machine learning models 602₁ to 602ₙ as well as second range data 604B about a range of possible values of at least one second control parameter used to control the control unit 607. The second range data 604B includes a range of all possible values of the second control parameter. Examples of the second control parameter are discussed elsewhere herein, which also applies here.

Method step S6 includes determining, using the processing unit 601, a second machine learning model 602ₘ of the plurality 602 of machine learning models 602₁ to 602ₙ based on the second data. Determining the second machine learning model 602ₘ may additionally be based on the determined control value 605A of the first control parameter, where m is an integer for which applies: 1≤m≤n.

Method step S7 includes providing the object data 603 and the second range data 604B as input data to the second machine learning model 602ₘ.

Method step S8 includes determining, using the second machine learning model 602ₘ, a control value 605B of the second control parameter, where the control value 605B of the second control parameter is an output of the second machine learning model 602ₘ. For example, the second machine learning model 602ₘ uses the object data 603 and the second range data 604B to determine the control value 605B of the second control parameter. The control value 605B of the second control parameter is used to provide the information about the object 15 at a later stage of the method according to the system described herein.

Method step S9 includes using the determined control value 605A of the first control parameter and the determined control value 605B of the second control parameter to operate the control unit 607.

Method step S10 includes generating, using the beam device 1000 in the form of the SEM 100 and the control unit 607 in the form of the control device 123, the information about the object 15.

In an embodiment of the method according to the system described herein, method step S10 includes generating an image of the object 15. In other words, an image of the object 15 is generated using the SEM 100. Additionally or alternatively, the method step S10 includes generating a spectroscopy analysis about the object 15. For example, interaction radiation of an interaction between the electron beam of the SEM 100 and the object 15 is detected using the radiation detector 500. The interaction radiation may be X-ray radiation or cathodoluminescent light.

In an embodiment of the method according to the system described herein, the first machine learning model 602ₖ and the second machine learning model 602ₘ may be identical. Therefore, the method according to the system described herein uses the same machine learning model for several control parameters (for example, the first control parameter and the second control parameter). The method steps according to the system described herein with respect to the several control parameters may be carried out simultaneously.

In a further embodiment of the method according to the system described herein, the first machine learning model 602ₖ is different to the second machine learning model 602ₘ.

The system described herein provides the processing unit 601 which determines which machine learning model 602ᵢ of the plurality 602 of machine learning models 602₁ to 602ₙ is to be used to determine the control value 605A of the first control parameter and to determine the control value 605B of the second control parameter. The processing unit 601 takes a decision based on the first data, on the one hand, and the second data and, in particular, the determined control value 605A of the first control parameter on the other hand. Therefore, the system described herein provides for the processing unit 601 to choose a specific machine learning model 602ᵢ from the plurality 602 of machine learning models 602₁ to 602ₙ which machine learning model may determine specific control values of the first control parameter and of the second control parameter. The specific control values of the first control parameter and of the second control parameter are used to operate the control unit 607 to generate the information about the object 15, in particular, in a rather short time and/or in a good quality. The method according to the system described herein also provides that each machine learning model 602₁ to 602ₙ used in the method according to the system described herein may use different ranges of possible values of the first control parameter and the second control parameter when determining the control values 605A, 605B of the first control parameter and the second control parameter. Therefore, the processing unit 601 may always choose a specific machine learning model 602ᵢ from the plurality 602 of machine learning models, where the specific machine learning model 602ᵢ may operate better than other machine learning models 602₁ to 602ₙ of the plurality 602 of machine learning models 602₁ to 602ₙ for a specific range of possible values of the first control parameter or the second control parameter.

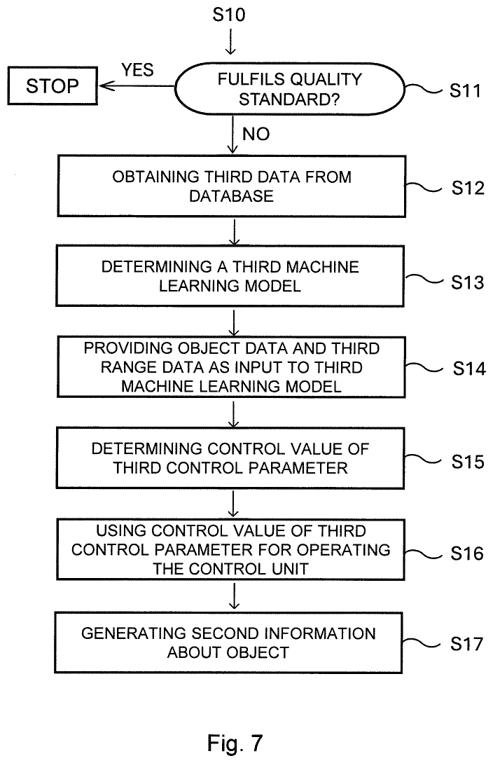

FIG. 7 schematically shows a flowchart of a further embodiment of the method used for operating the SEM 100 of FIG. 1. The further embodiment uses an additional control parameter to generate the information about the object 15. The method steps of the further embodiment may be carried out after method step S10 of the embodiment of the method of FIG. 6. The information about the object 15 generated in method step S10 is a first information about the object 15. Method step S11 includes determining, using the processing unit 601, whether the first information about the object 15 fulfils a desired quality standard. The desired quality standard may be given by a user or may be determined as discussed elsewhere herein, which also applies here. If the desired quality standard is fulfilled, the method may stop. If the desired quality standard is not fulfilled, the following steps of the method according to the system described herein may be carried out.

Method step S12 includes obtaining, using the processing unit 601, third data from the database 606. The third data includes the object data about the object 15, the data about the plurality 602 of machine learning models 602₁ to 602ₙ as well as third range data about a range of possible values of at least a third control parameter used to control the control unit 607 in the form of the control device 123 of the SEM 100. The third control parameter may be any control parameter used to control the control unit 607, for example at least one of the control parameters as mentioned elsewhere herein.

Method step S13 includes determining, using the processing unit 601, a third machine learning model 602ₚ of the plurality 602 of machine learning models 602₁ to 602ₙ based on the third data. Determining the third machine learning model 602ₚ may additionally be based on the determined control value 605A of the first control parameter and/or on the determined control value 605B of the second control parameter, where p is an integer for which applies: 1≤p≤n. The third machine learning model 602p may be one of the machine learning models mentioned elsewhere herein.

Method step S14 includes providing the object data 603 and the third range data as input data to the third machine learning model 602ₚ.

Method step S15 includes determining, using the third machine learning model 602p, a control value of the third control parameter, where the control value of the third control parameter is an output of the third machine learning model 602ₚ.

Method step S16 includes using the determined control value of the third control parameter to operate the control unit 607. As mentioned above, the determined control value 605A of the first control parameter and the determined control value 605B of the second control parameter are also used to operate the control unit 607.

Method step S17 includes generating, using the beam device 1000 in the form of the SEM 100 and the control unit 607, second information about the object 15. For example, an image of the object 15 is generated. Additionally or alternatively, a spectroscopy analysis about the object 15 is generated. For example, interaction radiation of an interaction between the electron beam of the SEM 100 and the object 15 is detected using the radiation detector 500. The interaction radiation may be X-ray radiation or cathodoluminescent light.

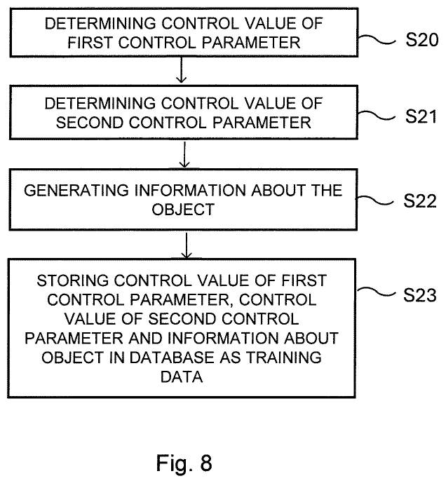

FIG. 8 schematically shows a flowchart of a computer-implemented method for generating a training dataset for (a) the processing unit 601 associated with the SEM 100 and/or for (b) a machine learning model 602₁ to 602ₙ. This training dataset is used to train the processing unit 601 and/or the machine learning model 602₁ to 602ₙ.

Method step S20 of the computer-implemented method includes determining the control value 605A of the first control parameter using the method of FIG. 6. Additionally, method step S21 of the computer-implemented method includes determining the control value 605B of the second control parameter using the method of FIG. 6. Method step 22 of the computer-implemented method includes generating, using the SEM 100 and the control unit 607, the information about the object 15, where the control unit 607 is controlled using the determined control value 605A of the first control parameter and the determined control value 605B of the second control parameter, which is discussed further above and also applies here. Method step S23 of the computer-implemented method includes storing the determined control value 605A of the first control parameter, the determined control value 605B of the second control parameter and the generated information about the object 15 in the database 606 as the training dataset. The training dataset may now be used to train the processing unit 601 and/or the machine learning model 602₁ to 602ₙ. Training the processing unit 601 and/or the machine learning model 602₁ to 602ₙ is known in the art. Therefore, training the processing unit 601 and/or the machine learning model 602₁ to 602ₙ as such is not discussed in detail.

As mentioned above, embodiments of the system described herein include determining whether the information about the object 15 fulfils a desired quality standard. For example, it is determined whether the image of the object 15 fulfils a desired quality standard. The desired quality standard may be given by a user or may be determined as discussed elsewhere herein, which also applies here.

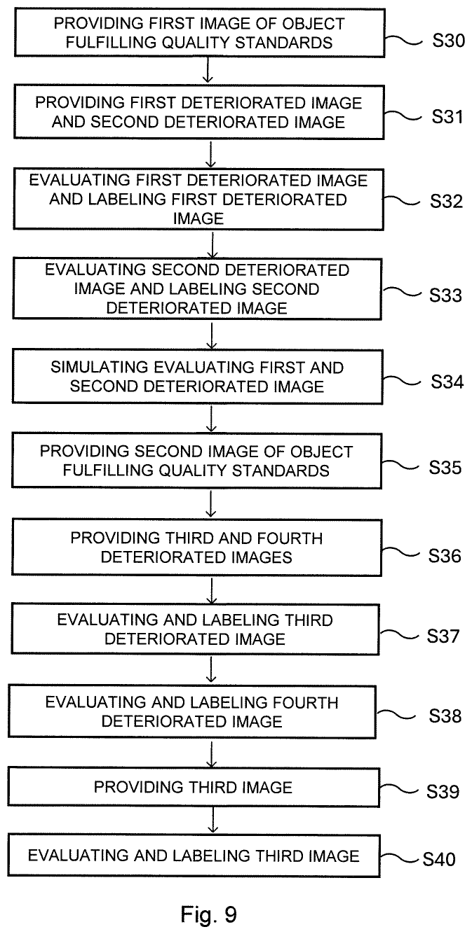

FIG. 9 schematically shows a flowchart of a method for training the machine learning model 602₁ to 602ₙ of the SEM 100 to identify an image of an object 15 which fulfils quality standards given by a user. After the machine learning model 602₁ to 602ₙ has been trained using the method of FIG. 9, the machine learning model 602₁ to 602ₙ is able to identify whether an image of the object 15 fulfils desired quality standards.

Method step S30 of the method of FIG. 9 includes providing, by a user of the SEM 100, a first image of the object 15 using the SEM 100, where the first image fulfils the quality standards. Embodiments of how to define the quality standards are discussed elsewhere herein, which also applies here.

Method step S31 of the method of FIG. 9 includes providing a first deteriorated image by deteriorating the first image using the processing unit 601 and providing a second deteriorated image by deteriorating the first image using the processing unit 601. In other words, the first image is worsened to obtain the first deteriorated image and the second deteriorated image.

Method step S32 of the method of FIG. 9 includes evaluating, by the user, whether the first deteriorated image fulfils the quality standards. The first deteriorated image is labeled depending on evaluating the first deteriorated image. Method step S33 of the method of FIG. 9 includes evaluating, by the user, whether the second deteriorated image fulfils the quality standards. The second deteriorated image is labeled depending on evaluating the second deteriorated image. Method steps S32 and S33 are carried out by the user of the SEM 100.

Method step S34 of the method of FIG. 9 follows the step S33 and is carried out using the machine learning model 602₁ to 602ₙ. Method step S34 includes simulating, using the machine learning model 602₁ to 602ₙ, (a) evaluating the first deteriorated image and (b) evaluating the second deteriorated image. The first image, the first deteriorated image and the second deteriorated image are used as training data for the machine learning model 602₁ to 602ₙ. Simulating is based on the first image, the first deteriorated image and the second deteriorated image.

Method step S35 of the method of FIG. 9 is carried out by the user of the SEM 100. Method step S35 of the method of FIG. 9 includes an optional step of providing, by the user of the SEM 100, a second image of the object 15 using the SEM 100, where the second image fulfils the quality standards.

Method step S36 of the method of FIG. 9 includes providing a third deteriorated image by deteriorating the first image and/or the second image using the processing unit 601 of the SEM 100 and (b) providing a fourth deteriorated image by deteriorating the first image and/or the second image using the processing unit 601 of the SEM 100.

Method step S37 of the method of FIG. 9 uses the machine learning model 602₁ to 602ₙ. Method step S37 of the method of FIG. 9 includes evaluating, using the machine learning model 602₁ to 602ₙ, whether the third deteriorated image fulfils the quality standards. The third deteriorated image is labeled depending on evaluating the third deteriorated image. Evaluating and labeling the third deteriorated image are repeated, until it is verified, using the control unit 607 or the processing unit 601, whether the labeling is correctly done.

Method step S38 of the method of FIG. 9 uses the machine learning model 602₁ to 602ₙ. Method step S38 of the method of FIG. 9 includes evaluating, using the machine learning model 602₁ to 602ₙ, whether the fourth deteriorated image fulfils the quality standards. The fourth deteriorated image is labeled depending on evaluating the fourth deteriorated image. Evaluating and labeling the fourth deteriorated image are repeated, until it is verified, using the control unit 607 or the processing unit 601, whether the labeling is correctly done.

Method step S39 of the method of FIG. 9 includes providing, by the user and/or the processing unit 601 of the SEM 100, a third image of the object. Method step S40 of the method of FIG. 9 is carried out by the machine learning model 602₁ to 602ₙ. The machine learning model 602₁ to 602ₙ evaluates and labels the third image without knowing upfront whether the third image fulfils the quality standards. Method step S40 of the method of FIG. 9 includes evaluating, using the machine learning model 602₁ to 602ₙ, whether the third image fulfils the quality standards. The third image is labeled by the machine learning model 602₁ to 602ₙ, depending on evaluating the third image. Evaluating and labeling the third image are repeated, until it is verified, using the control unit 607 or the processing unit 601, whether the labeling is correctly done.

After the machine learning model 602₁ to 602ₙ has been trained using the method of FIG. 9, the machine learning model 602₁ to 602ₙ is able to identify whether an image of the object 15 fulfils desired quality standards.

All of the above and following embodiments of the method according to the invention are not limited to the explained sequence of method steps. The invention also includes different sequences of the method steps which are suitable to achieve the object of the invention. Additionally or alternatively, a parallel execution of at least two method steps is also provided in the method according to the invention. Furthermore, the above and following embodiments of the method according to the invention are not limited to the entirety of all method steps mentioned elsewhere herein. In particular, it is intended that in further embodiments individual or several of the method steps mentioned herein are omitted.

The features of the invention disclosed in the present description, in the drawings and in the claims may be essential for the realization of the invention in the various embodiments thereof, both individually and in arbitrary combinations. The invention is not restricted to the described embodiments. The invention may be varied within the scope of the claims, taking into account the knowledge of the relevant person skilled in the art.

1. A method for operating a beam device to obtain information about an object, comprising:
obtaining, using a processing unit, first data from a database that is connected to the processing unit, wherein the first data includes object data about the object, data about a plurality of machine learning models and first range data about a range of possible values of at least one first control parameter used to control a control unit of the beam device;
determining, using the processing unit, a first machine learning model of the plurality of machine learning models based on the first data;
providing the object data and the first range data as input data to the first machine learning model;
determining, using the first machine learning model, a control value of the first control parameter, wherein the control value of the first control parameter is an output of the first machine learning model;
obtaining, using the processing unit, second data from the database, wherein the second data includes the object data about the object, the data about the plurality of machine learning models as well as second range data about a range of possible values of at least one second control parameter to control the control unit of the beam device;
determining, using the processing unit, a second machine learning model of the plurality of machine learning models based on the second data;
providing the object data and the second range data as input data to the second machine learning model;
determining, using the second machine learning model, a control value of the second control parameter, wherein the control value of the second control parameter is an output of the second machine learning model;
using the control value of the first control parameter and the control value of the second control parameter to operate the control unit; and
generating, using the beam device and the control unit of the beam device, the information about the object.

2. The method according to claim 1, wherein determining, using the processing unit, the second machine learning model of the plurality of machine learning models is additionally based on the determined control value of the first control parameter.

3-4. (canceled)

5. The method according to claim 1, wherein determining the first machine learning model and/or the second machine learning model includes determining a heuristic autotuning algorithm machine learning model, a supervised learning algorithm machine learning model, or a reinforcement algorithm machine learning model.

6.-9. (canceled)

10. The method according to claim 1, wherein the information about the object is first information about the object, the method further comprising:
determining, using the processing unit, whether the first information about the object fulfils a desired quality standard; and
if the desired quality standard is not fulfilled, performing the following:
obtaining, using the processing unit, third data from the database being connected to the processing unit, wherein the third data includes the object data about the object, the data about the plurality of machine learning models as well as third range data about a range of possible values of at least a third control parameter used to control the control unit of the beam device;
determining, using the processing unit, a third machine learning model of the plurality of machine learning models based on the third data;
providing the object data and the third range data as input data to the third machine learning model;
determining, using the third machine learning model, a control value of the third control parameter, wherein the control value of the third control parameter is an output of the third machine learning model;
using the control value of the third control parameter to operate the control unit; and
generating, using the beam device and the control unit of the beam device, second information about the object.

11. The method according to claim 10, wherein determining the third machine learning model is additionally based on the control value of the first control parameter and/or the control value of the second control parameter.

12.-13. (canceled)

14. A non-transitory computer readable medium containing software that is loadable into a processing unit and which, when executed by the processing unit, controls a beam device to perform the following:
obtaining first data from a database that is connected to the processing unit, wherein the first data includes object data about the object, data about a plurality of machine learning models and first range data about a range of possible values of at least one first control parameter used to control a control unit of the beam device;
determining a first machine learning model of the plurality of machine learning models based on the first data;
providing the object data and the first range data as input data to the first machine learning model;
determining, using the first machine learning model, a control value of the first control parameter, wherein the control value of the first control parameter is an output of the first machine learning model;
obtaining second data from the database, wherein the second data includes the object data about the object, the data about the plurality of machine learning models as well as second range data about a range of possible values of at least one second control parameter to control the control unit of the beam device;
determining a second machine learning model of the plurality of machine learning models based on the second data;
providing the object data and the second range data as input data to the second machine learning model;
determining, using the second machine learning model, a control value of the second control parameter, wherein the control value of the second control parameter is an output of the second machine learning model;
using the control value of the first control parameter and the control value of the second control parameter to operate the control unit; and
generating, using the beam device and the control unit of the beam device, the information about the object.

15. A beam device for generating information about an object, comprising:
at least one beam generator that generates a beam;
at least one objective lens that focuses the beam onto the object;
at least one detector unit that detects interaction particles and/or interaction radiation resulting from an interaction of the beam with the object;
at least one processing unit coupled to the beam device; and
at least one non-transitory computer readable medium, coupled to the at least one processing unit and containing software that is loadable into the at least one processing unit and which, when executed by the at least one processing unit, controls the beam device to perform the following:
obtaining first data from a database that is connected to the at least one processing unit, wherein the first data includes object data about the object, data about a plurality of machine learning models and first range data about a range of possible values of at least one first control parameter used to control a control unit of the beam device;
determining a first machine learning model of the plurality of machine learning models based on the first data;
providing the object data and the first range data as input data to the first machine learning model;
determining, using the first machine learning model, a control value of the first control parameter, wherein the control value of the first control parameter is an output of the first machine learning model;
obtaining second data from the database, wherein the second data includes the object data about the object, the data about the plurality of machine learning models as well as second range data about a range of possible values of at least one second control parameter to control the control unit of the beam device;
determining a second machine learning model of the plurality of machine learning models based on the second data;
providing the object data and the second range data as input data to the second machine learning model;
determining, using the second machine learning model, a control value of the second control parameter, wherein the control value of the second control parameter is an output of the second machine learning model;
using the control value of the first control parameter and the control value of the second control parameter to operate the control unit; and
generating, using the beam device and the control unit of the beam device, the information about the object.

16. The beam device according to claim 15, wherein the beam device is at least one of: a light microscope for imaging and/or analyzing the object and/or a laser beam device for imaging, processing and/or analyzing the object.

17. The beam device according to claim 15, wherein the beam device is a particle beam device for imaging, that images, processes, and/or analyzes the object.

18. The beam device according to claim 17, wherein
the beam generator is a particle beam generator that generates a particle beam with charged particles,
the objective lens is an objective lens that focuses the particle beam onto the object,
the detector unit is a detector unit that detects interaction particles and/or interaction radiation resulting from the interaction of the particle beam with the object, and wherein the beam device includes
at least one scanning device that scans the particle beam over the object.

19. The beam device according to claim 18, wherein the particle beam generator is a first particle beam generator and the particle beam is a first particle beam with first charged particles, wherein the objective lens is a first objective lens that focuses the first particle beam onto the object, the beam device further comprising:
at least one second particle beam generator that generates a second particle beam with second charged particles; and
at least one second objective lens that focuses the second particle beam onto the object.

20. The beam device according to claim 15, wherein the beam device is an electron beam device and/or an ion beam device.

21. A method for generating a training dataset for a processing unit of a beam device and/or a machine learning model that determines a control value of a first control parameter to operate a control unit of the beam device and a control value of a second control parameter to operate the control unit of the beam device, the method comprising:
determining the control value of the first control parameter by obtaining, using the processing unit, first data from a database that is connected to the processing unit, wherein the first data includes object data about the object, data about a plurality of machine learning models and first range data about a range of possible values of the first control parameter used to control a control unit of the beam device, determining, using the processing unit, a first machine learning model of the plurality of machine learning models based on the first data, providing the object data and the first range data as input data to the first machine learning model, and determining, using the first machine learning model, the control value of the first control parameter, wherein the control value of the first control parameter is an output of the first machine learning model;
determining the control value of the second control parameter by obtaining, using the processing unit, second data from a database that is connected to the processing unit, wherein the second data includes object data about the object, data about a plurality of machine learning models and second range data about a range of possible values of the second control parameter used to control a control unit of the beam device, determining, using the processing unit, a second machine learning model of the plurality of machine learning models based on the second data, providing the object data and the second range data as input data to the second machine learning model, and determining, using the second machine learning model, a control value of the second control parameter, wherein the control value of the second control parameter is an output of the second machine learning model;
generating, using the beam device and the control unit of the beam device, the information about the object; and
storing the determined control value of the first control parameter, the control value of the second control parameter and the information about the object in a database as the training dataset.

22. A method for training a machine learning model the of a beam device to identify an image of an object which fulfils quality standards given by a user, the method comprising:
a user of the beam device providing a first image of an object using a beam device, wherein the first image fulfils the quality standards;
providing at least a first deteriorated image by deteriorating the first image using a processing unit associated with the beam device and providing at least a second deteriorated image by deteriorating the first image using the processing unit associated with the beam device;
the user evaluating whether the at least one first deteriorated image fulfils the quality standards and labeling the at least one first deteriorated image depending on evaluating the at least one first deteriorated image;
the user evaluating whether the at least one second deteriorated image fulfils the quality standards and labeling the at least one second deteriorated image depending on evaluating the at least one second deteriorated image;
simulating, using the machine learning model, evaluating the at least one first deteriorated image and evaluating the at least one second deteriorated image, wherein the first image, the at least one first deteriorated image and the at least one second deteriorated image are used as training data for the machine learning model and wherein simulating is based on the first image, the at least one first deteriorated image and the at least one second deteriorated image;
the user of the beam device providing a second image of the object using the beam device, wherein the second image fulfils the quality standards;
providing at least a third deteriorated image by deteriorating the first image and/or the second image using the processing unit associated with the beam device and providing at least a fourth deteriorated image by deteriorating the first image and/or the second image using the processing unit associated with the beam device;
evaluating, using the machine learning model, whether the at least one third deteriorated image fulfils the quality standards and labeling the at least one third deteriorated image depending on evaluating the at least one third deteriorated image, wherein evaluating and labeling the at least one third deteriorated image are repeated, until correctness of the label is verified, using the processing unit associated with the beam device;
evaluating, using the machine learning model, whether the at least one fourth deteriorated image fulfils the quality standards and labeling the at least one fourth deteriorated image depending on evaluating the at least one fourth deteriorated image, wherein evaluating and labeling the at least one fourth deteriorated image are repeated, until correctness of the label is verified, using the processing unit associated with the beam device;
the user and/or the processing unit associated with the beam device providing at least one third image of the object; and
evaluating, using the machine learning model, whether the at least one third image fulfils the quality standards and labeling the at least one third image depending on evaluating the at least one third image, wherein evaluating and labeling the at least one third image are repeated, until correctness of the label is verified, using the processing unit associated with the beam device.

23. The method according to claim 1, wherein the first machine learning model and the second machine learning model are identical or the first machine learning model is different from the second machine learning model.

24. The method according to claim 1, wherein generating the information about the object generates an image of the object or generates a spectroscopy analysis about the object.

25. The method according to claim 1, wherein the first control parameter is at least one of: a first physical variable, a first control current, a first control voltage, a first ratio of physical variables, or a first amplification of physical variables.

26. The method according to claim 1, wherein the second control parameter is at least one of: a second physical variable, a second control current, a second control voltage, a second ratio of physical variables, or a second amplification of physical variables.

27. The method according to claim 1, wherein the first control parameter is one of: a first contrast parameter that sets the contrast of the information about the object, a first brightness parameter that sets the brightness of the information about the object, a first actuating parameter that actuates an objective lens of the beam device, a first setting parameter that sets an electrostatic and/or magnetic unit of the beam device, a first controlling parameter that controls and sets an electrostatic and/or magnetic deflection unit of the beam device to achieve a shift of the beam of the beam device and a first stigmator parameter that sets a stigmator of the beam device and wherein the second control parameter is one of: a second contrast parameter that sets the contrast of the information about the object, a second brightness parameter that sets the brightness of the information about the object, a second actuating parameter that actuates the objective lens of the beam device, a second setting parameter that sets the electrostatic and/or magnetic unit of the beam device, a second controlling parameter that controls and sets the electrostatic and/or magnetic deflection unit of the beam device to achieve a shift of the beam of the beam device and a second stigmator parameter that sets the stigmator of the beam device.

28. The method according to claim 1, wherein the first control parameter is between a minimum value and a maximum value that depend on a configuration of the control unit and/or
wherein of the first control parameter is configured as a first contrast parameter that sets a contrast of the information about the object and is between a minimum value and a maximum value that depend on a configuration of the control unit and/or
wherein the first control parameter is configured as a first brightness parameter that sets a brightness of the information about the object and is between a minimum value and a maximum value that depend on a configuration of the control unit and/or
wherein the first control parameter is configured as a first actuating parameter that actuates an objective lens of the beam device and is between a minimum value and a maximum value that depend on a configuration of the control unit and/or
wherein the second control parameter is between a minimum value and a maximum value that depend on a configuration of the control unit and/or
wherein the second control parameter is configured as a second contrast parameter that sets a contrast of the information about the object and is between a minimum value and a maximum value that depend on a configuration of the control unit and/or
wherein the second control parameter is configured as a second brightness parameter that sets a brightness of the information about the object and is between a minimum value and a maximum value that depend on a configuration of the control unit and/or
wherein the second control parameter is configured as a second actuating parameter that actuates an objective lens of the beam device and is between a minimum value and a maximum value that depend on a configuration of the control unit.

29. The method according to claim 10, wherein the second information about the object is an image of the object or a spectroscopy analysis about the object.

30. The method according to claim 1, wherein the beam device is at least one of: a light microscope, a laser beam device, a particle beam device, an electron beam device, and an ion beam device.
